(19) United States
(12) Patent Application Publication
(10) Pub. No.: US 2022/0262841 A1
(43) Pub. Date: Aug. 18, 2022

(54) SEMICONDUCTOR PACKAGE, ELECTRONIC DEVICE, AND METHOD OF MANUFACTURING SEMICONDUCTOR PACKAGE

(71) Applicant: SONY SEMICONDUCTOR SOLUTIONS CORPORATION, KANAGAWA (JP)

(72) Inventors: HIROYUKI SHIGETA, KANAGAWA (JP); KOHYOH HOSOKAWA, KANAGAWA (JP); JO UMEZAWA, KANAGAWA (JP); MASAKI HATANO, KANAGAWA (JP); HIROFUMI MAKINO, KANAGAWA (JP); TOSHIKI KOYAMA, KANAGAWA (JP)

(21) Appl. No.: 17/627,288

(22) PCT Filed: May 22, 2020
(86) PCT No.: PCT/JP2020/020225

§ 371 Date: Jan. 14, 2022

(30) Foreign Application Priority Data
Jul. 23, 2019 (JP) 2019-135117

(51) Int. Cl. H01L 27/146

(52) U.S. Cl. CPC H01L 27/14634; H01L 27/14618; H01L 24/96; H01L 27/14636; H01L 27/1469

(57) ABSTRACT

Circuits are added while an increase in size of a semiconductor package is prevented. The semiconductor package includes a transparent member; an embedding resin; an embedded circuit; and a solid-state image pickup element. In the semiconductor package, the embedding resin is formed around the transparent member. Further, in the semiconductor package, the embedded circuit is embedded in the embedding resin. Further, in the semiconductor package, the solid-state image pickup element performs photoelectric conversion on light that has passed through the transparent member and thereby generates image data.

### TECHNICAL FIELD

The present technology relates to a semiconductor package. Specifically, the present technology relates to a semiconductor package configured to generate image data, an electronic device, and a method of manufacturing the semiconductor package.

### BACKGROUND ART

Hitherto, in order to realize easy handling of a semiconductor integrated circuit, a semiconductor package in which the semiconductor integrated circuit is implemented on a substrate and sealed has been used. For example, there is proposed a semiconductor package in which an image sensor is implemented inside a frame member as a semiconductor integrated circuit and the upper portion of the frame member is covered with glass to seal the semiconductor integrated circuit (for example, see PTL 1).

### CITATION LIST

### Patent Literature

### [PTL 1]

Japanese Patent No. 5885690

### SUMMARY

### Technical Problems

However, in the related art described above, it is difficult to add circuits without changing the size of the semiconductor package. Circuits can be added using the SiP (System in Package) technology that encloses a plurality of semiconductor chips connected to each other in a single package, but the size of the semiconductor package is increased. For example, a SiP including a semiconductor chip and an additional semiconductor chip that are arranged side by side has a larger semiconductor package area. Further, a SiP including a plurality of semiconductor chips stacked has a larger semiconductor package thickness. As described above, the related art described above has a problem in that it is impossible to add circuits while preventing an increase in size of the semiconductor package.

The present technology has been made in view of such a circumstance and has an object to add circuits to a semiconductor package including a solid-state image pickup element while preventing an increase in size of the semiconductor package.

### Solution to Problems

In order to solve the problems described above, according to a first aspect of the present technology, there are provided a semiconductor package including a transparent member; an embedding resin formed around the transparent member; an embedded circuit embedded in the embedding resin; and a solid-state image pickup element configured to perform photoelectric conversion on light that has passed through the transparent member and thereby generate image data, and a method of manufacturing the semiconductor package. This provides an action that, with the circuit embedded in the embedding resin, the function of the semiconductor package is enhanced.

Further, in the first aspect, a redistribution layer having wired therein a signal line for connecting the embedded circuit and the solid-state image pickup element to each other may further be included. This provides an action that data is transmitted between the embedded circuit and the solid-state image pickup element.

Further, in the first aspect, an external terminal disposed in a fan-out area may further be included. This provides an action that data transmission is established with an external device via the external terminal disposed in the fan-out area.

Further, in the first aspect, an external terminal disposed in each of a fan-out area and a fan-in area may further be included. This provides an action that data transmission is established with an external device via the external terminal disposed in each of the fan-out area and the fan-in area.

Further, in the first aspect, a frame that has an opening portion formed in an area corresponding to the transparent member and is laminated on the embedding resin may further be included. This provides an action that the heat release property is enhanced and the semiconductor package is thus reinforced.

Further, in the first aspect, a ceramic substrate having formed therein a recess and an external terminal formed on the ceramic substrate may further be included, and the solid-state image pickup element may be provided in the recess and connected to the ceramic substrate with a wire. This provides an action that the function of the ceramic package is enhanced.

Further, in the first aspect, a heater configured to heat the transparent member in a case where humidity in the recess exceeds a predetermined threshold may further be included, and the embedded circuit may include a humidity sensor configured to measure the humidity and detect whether the humidity exceeds the threshold or not. This provides an action that the transparent member is heated depending on humidity.

Further, in the first aspect, the embedded circuit may include a control circuit configured to control an optical property of the transparent member. This provides an action that the optical property of the transparent member is adjusted.

Further, in the first aspect, an antenna may further be included, and the embedded circuit may include a wireless circuit configured to perform wireless communication via the antenna. This provides an action that a wireless communication function is realized.

Further, in the first aspect, a heat release member embedded in the embedding resin may further be included, and the heat release member may release heat generated by the embedded circuit. This provides an action that a temperature rise that may be caused by the embedded circuit is prevented.

Further, in the first aspect, the heat release member may have a columnar shape. This provides an action that, with the columnar heat release member, a temperature rise that may be caused by the embedded circuit is prevented.

Further, in the first aspect, a resin dam formed between a periphery of a pixel array portion of the solid-state image pickup element and the transparent member may further be included. This provides an action that the solid-state image pickup element and the transparent member are spaced apart from each other.

Further, in the first aspect, the solid-state image pickup element may be connected to the transparent member via a bump. This provides an action that a chip shift is prevented.

Further, according to a second aspect of the present technology, there is provided an electronic device including a transparent member; an embedding resin formed around the transparent member; an embedded circuit embedded in the embedding resin; a solid-state image pickup element configured to perform photoelectric conversion on light that has passed through the transparent member and thereby generate image data; and an optical section configured to collect incident light and guide the incident light to the transparent member. This provides an action that, with the circuit embedded in the embedding resin, the function of the electronic device is enhanced.

### BRIEF DESCRIPTION OF DRAWINGS

FIG. 1 is a block diagram illustrating a configuration example of an electronic device according to a first embodiment of the present technology.

FIG. 2 is a sectional view illustrating a configuration example of a semiconductor package according to the first embodiment of the present technology.

FIG. 3 is an exemplary plan view of the semiconductor package according to the first embodiment of the present technology.

FIG. 4 is an exemplary plan view of the semiconductor package including an additional embedded circuit according to the first embodiment of the present technology.

FIG. 5 depicts diagrams illustrating the manufacturing processes of the semiconductor package up to the formation of a redistribution layer according to the first embodiment of the present technology.

FIG. 6 depicts diagrams illustrating the manufacturing processes of the semiconductor package up to the dicing of an image sensor wafer according to the first embodiment of the present technology.

FIG. 7 depicts diagrams illustrating the manufacturing processes of the semiconductor package up to the formation of external terminals according to the first embodiment of the present technology.

FIG. 8 depicts diagrams illustrating the processes up to dicing according to the first embodiment of the present technology.

FIG. 9 is a flowchart illustrating an exemplary manufacturing process of the semiconductor package according to the first embodiment of the present technology.

FIG. 10 depicts diagrams illustrating the manufacturing processes of the semiconductor package up to the formation of the redistribution layer according to a first modified example of the first embodiment of the present technology.

FIG. 11 depicts diagrams illustrating the manufacturing processes of the semiconductor package up to the dicing of the image sensor wafer according to the first modified example of the first embodiment of the present technology.

FIG. 12 depicts diagrams illustrating the manufacturing processes of the semiconductor package up to the formation of the external terminals according to the first modified example of the first embodiment of the present technology.

FIG. 13 is a diagram illustrating the process of dicing according to the first modified example of the first embodiment of the present technology.

FIG. 14 is a sectional view illustrating a configuration example of a semiconductor package according to a second modified example of the first embodiment of the present technology.

FIG. 15 depicts diagrams illustrating the manufacturing processes of the semiconductor package up to the formation of the redistribution layer according to the second modified example of the first embodiment of the present technology.

FIG. 16 depicts diagrams illustrating the manufacturing processes of the semiconductor package up to dicing according to the second modified example of the first embodiment of the present technology.

FIG. 17 depicts diagrams illustrating the manufacturing processes of the semiconductor package up to wire bonding according to the second modified example of the first embodiment of the present technology.

FIG. 18 is a sectional view illustrating a configuration example of a semiconductor package according to a third modified example of the first embodiment of the present technology.

FIG. 19 is a sectional view illustrating a configuration example of a semiconductor package according to a second embodiment of the present technology.

FIG. 20 is an exemplary top view of the semiconductor package according to the second embodiment of the present technology.

FIG. 21 is an exemplary bottom view of the semiconductor package according to the second embodiment of the present technology.

FIG. 22 depicts diagrams illustrating the manufacturing processes of the semiconductor package up to the embedding of circuits according to the second embodiment of the present technology.

FIG. 23 depicts diagrams illustrating the manufacturing processes of the semiconductor package up to flip chip connection according to the second embodiment of the present technology.

FIG. 24 depicts diagrams illustrating the manufacturing processes of the semiconductor package up to the formation of external terminals according to the second embodiment of the present technology.

FIG. 25 is a diagram illustrating the process of dicing according to the second embodiment of the present technology.

FIG. 26 is a sectional view illustrating a configuration example of a semiconductor package according to a third embodiment of the present technology.

FIG. 27 depicts diagrams illustrating the manufacturing processes of the semiconductor package up to the formation of holes according to the third embodiment of the present technology.

FIG. 28 depicts diagrams illustrating the manufacturing processes of the semiconductor package up to lay-up according to the third embodiment of the present technology.

FIG. 29 is a diagram illustrating the process of pressing layers together according to the third embodiment of the present technology.

FIG. 30 is a sectional view illustrating a configuration example of a semiconductor package according to a fourth embodiment of the present technology.

FIG. 31 is an exemplary top view of the semiconductor package according to the fourth embodiment of the present technology.

FIG. 32 is an exemplary sectional view of the semiconductor package according to the fourth embodiment of the present technology.

FIG. 33 depicts diagrams illustrating the manufacturing processes of the semiconductor package up to the formation of a measurement hole according to the fourth embodiment of the present technology.

FIG. 34 depicts diagrams illustrating the manufacturing processes of the semiconductor package up to wire bonding according to the fourth embodiment of the present technology.

FIG. 35 is a sectional view illustrating a configuration example of a semiconductor package according to a first modified example of the fourth embodiment of the present technology.

FIG. 36 is an exemplary sectional view of the semiconductor package according to the first modified example of the fourth embodiment of the present technology.

FIG. 37 is a sectional view illustrating a configuration example of a semiconductor package according to a second modified example of the fourth embodiment of the present technology.

FIG. 38 is an exemplary sectional view of the semiconductor package according to the second modified example of the fourth embodiment of the present technology.

FIG. 39 is a sectional view illustrating a configuration example of a semiconductor package according to a fifth embodiment of the present technology.

FIG. 40 is an exemplary top view of the semiconductor package according to the fifth embodiment of the present technology.

FIG. 41 depicts diagrams illustrating the manufacturing processes of the semiconductor package up to the peeling off of a support substrate according to the fifth embodiment of the present technology.

FIG. 42 depicts diagrams illustrating the manufacturing processes of the semiconductor package up to the formation of the redistribution layer according to the fifth embodiment of the present technology.

FIG. 43 is a diagram illustrating the manufacturing process of a transparent member and a heat release member according to a first modified example of the fifth embodiment of the present technology.

FIG. 44 is a sectional view illustrating a configuration example of a semiconductor package according to a second modified example of the fifth embodiment of the present technology.

FIG. 45 depicts diagrams illustrating the manufacturing processes of the semiconductor package up to the mounting of a solid-state image pickup element and the embedded circuits according to the second modified example of the fifth embodiment of the present technology.

FIG. 46 is a diagram illustrating the process of forming the redistribution layer according to the second modified example of the fifth embodiment of the present technology.

FIG. 47 is a sectional view illustrating a configuration example of a semiconductor package according to a third modified example of the fifth embodiment of the present technology.

FIG. 48 depicts diagrams illustrating the manufacturing processes of the semiconductor package up to the mounting of the solid-state image pickup element and the embedded circuits according to the third modified example of the fifth embodiment of the present technology.

FIG. 49 is a diagram illustrating the process of forming the redistribution layer according to the third modified example of the fifth embodiment of the present technology.

FIG. 50 is a sectional view illustrating a configuration example of a semiconductor package according to a fourth modified example of the fifth embodiment of the present technology.

FIG. 51 is an exemplary top view of the semiconductor package according to the fourth modified example of the fifth embodiment of the present technology.

FIG. 52 is a block diagram depicting an example of schematic configuration of a vehicle control system.

FIG. 53 is a diagram of assistance in explaining an example of installation positions of an outside-vehicle information detecting section and an imaging section.

### DESCRIPTION OF EMBODIMENTS

Now, modes for carrying out the present technology (hereinafter referred to as “embodiments”) are described. The following items are described in the following order.

1. First embodiment (an example in which circuits are embedded around a transparent member)

2. Second embodiment (an example in which the circuits are embedded around the transparent member and external terminals are also provided in a fan-in)

3. Third embodiment (an example in which the circuits are embedded around the transparent member and a plurality of layers are laminated)

4. Fourth embodiment (an example in which the circuits are embedded around the transparent member and the transparent member is heated depending on humidity)

5. Fifth embodiment (an example in which the circuits are embedded around the transparent member and a heat release member is provided)

6. Application example to moving body

### 1. First Embodiment

### [Configuration Example of Electronic Device]

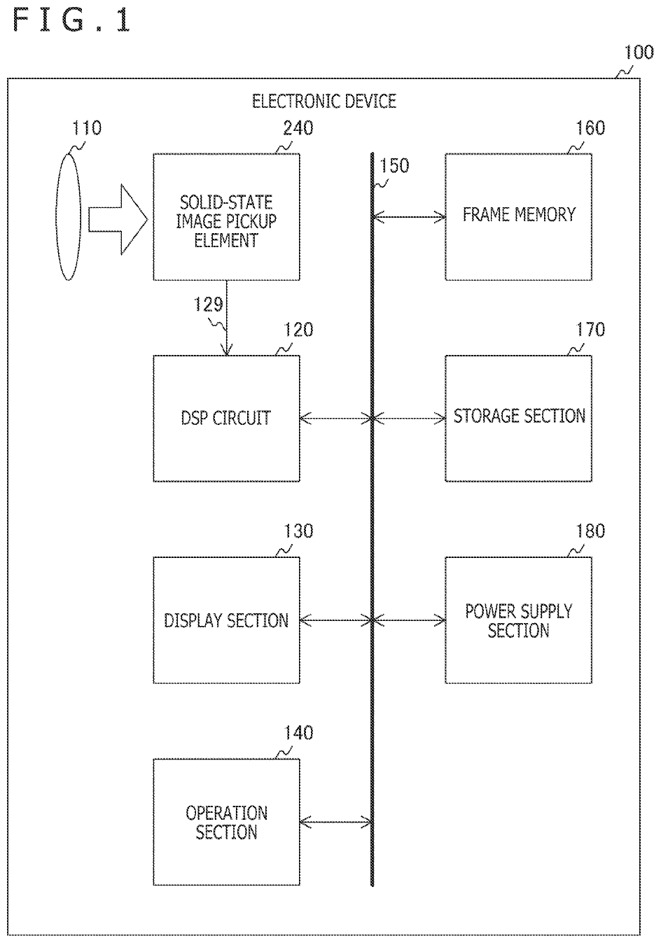

FIG. 1 is a block diagram illustrating a configuration example of an electronic device 100 according to a first embodiment of the present technology. The electronic device 100 is a device for capturing image data and includes an optical section 110, a solid-state image pickup element 240, and a DSP (Digital Signal Processing) circuit 120. The electronic device 100 further includes a display section 130, an operation section 140, a bus 150, a frame memory 160, a storage section 170, and a power supply section 180. As the electronic device 100, for example, a digital camera such as a digital still camera, a smartphone, a personal computer, or a vehicle-mounted camera is assumed.

The optical section 110 collects light from an object and guides the light to the solid-state image pickup element 240. The solid-state image pickup element 240 performs photoelectric conversion on incident light in synchronization with a vertical synchronization signal to generate image data. Here, the vertical synchronization signal is a periodic signal of a predetermined frequency indicating an image capturing timing. The solid-state image pickup element 240 supplies the generated image data to the DSP circuit 120.

The DSP circuit 120 executes predetermined signal processing on the image data supplied from the solid-state image pickup element 240. The DSP circuit 120 outputs the processed image data to the frame memory 160 or the like via the bus 150.

The display section 130 displays image data. As the display section 130, for example, a liquid crystal panel or an organic EL (Electro Luminescence) panel is assumed. The operation section 140 generates an operation signal on the basis of user operation.

The bus 150 is a common path for allowing the optical section 110, the solid-state image pickup element 240, the DSP circuit 120, the display section 130, the operation section 140, the frame memory 160, the storage section 170, and the power supply section 180 to exchange data therebetween.

The frame memory 160 holds image data. The storage section 170 stores various types of data such as image data. The power supply section 180 supplies power to the solid-state image pickup element 240, the DSP circuit 120, the display section 130, and the like.

In the configuration described above, for example, the solid-state image pickup element 240 and the DSP circuit 120 are implemented in a semiconductor package.

### [Configuration Example of Semiconductor Package]

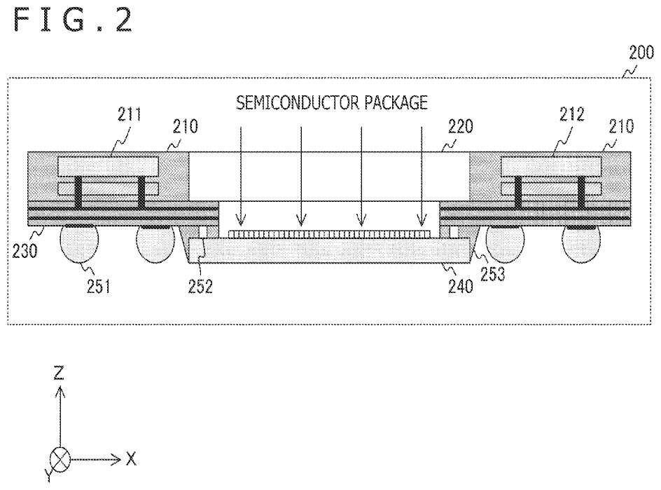

FIG. 2 is a sectional view illustrating a configuration example of a semiconductor package 200 according to the first embodiment of the present technology. The semiconductor package 200 includes an embedding resin 210, a transparent member 220, a redistribution layer 230, the solid-state image pickup element 240, external terminals 251, bumps 252, and an underfill material 253.

The transparent member 220 allows incident light from the optical section 110 to pass through it. As the transparent member 220, for example, glass is used. The arrows in FIG. 2 indicate the incident direction of incident light.

In the following, the optical axis of incident light is referred to as a “Z axis.” Further, a predetermined direction vertical to the Z axis is referred to as an “X axis,” and a direction vertical to the X axis and the Z axis is referred to as a “Y axis.” FIG. 2 is a sectional view from the Y-axis direction.

The embedding resin 210 is a resin formed around the transparent member 220 when seen from the Z-axis direction. In the embedding resin 210, circuits such as embedded circuits 211 and 212 are embedded. As the embedded circuit 211, for example, a circuit configured to process image data (DSP circuit 120 or the like) is provided. Further, as the embedded circuit 212, for example, a memory configured to hold image data is provided. Further, as the embedded circuit 211 or 212, a passive element or an active element can be disposed.

The redistribution layer 230 is an insulation layer having wired therein a signal line for electrically connecting the embedded circuits 211 and 212 and the solid-state image pickup element 240 to each other. The redistribution layer 230 is formed under the embedding resin 210 when the optical section 110 side is the upper side.

Further, when seen from the Z-axis direction, the redistribution layer 230 is open at its central portion, and the opening portion has a shape similar to the transparent member 220 but a slightly smaller area than the transparent member 220. Thus, when seen from the Z-axis direction, the inner-side portion of the redistribution layer 230 partly overlaps the periphery of the solid-state image pickup element 240. The bumps 252 are provided in the overlapping portion. The solid-state image pickup element 240 and the signal line in the redistribution layer 230 are electrically connected to each other via the bumps 252.

The external terminals 251 are formed on the area of the lower surface of the redistribution layer 230 that is on the outer side of the solid-state image pickup element 240. The outer-side area is also called a fan-out area. As the external terminals 251, for example, solder balls are provided.

The underfill material 253 is a member that wraps the connection portion between the solid-state image pickup element 240 and the redistribution layer 230 with no space and seals the connection portion in order to enhance the connection reliability. As the underfill material 253, resin or the like is used.

With the configuration described above, the solid-state image pickup element 240 performs photoelectric conversion on light that has passed through the transparent member 220 and thereby generates image data. In addition, the solid-state image pickup element 240 supplies the image data to the embedded circuit 211 or 212 via the signal line in the redistribution layer 230.

Further, as exemplified in FIG. 2, the semiconductor package 200 includes no package substrate. Instead, the redistribution layer 230 for drawing out the wiring from the terminals (bumps 252 or the like) of the chip (solid-state image pickup element 240 or the like) is formed by a wafer level process, which is described later, and is connected to the external terminals 251 in the fan-out area. Such a semiconductor package 200 is generally called a FOWLP (Fan Out Wafer Level Package).

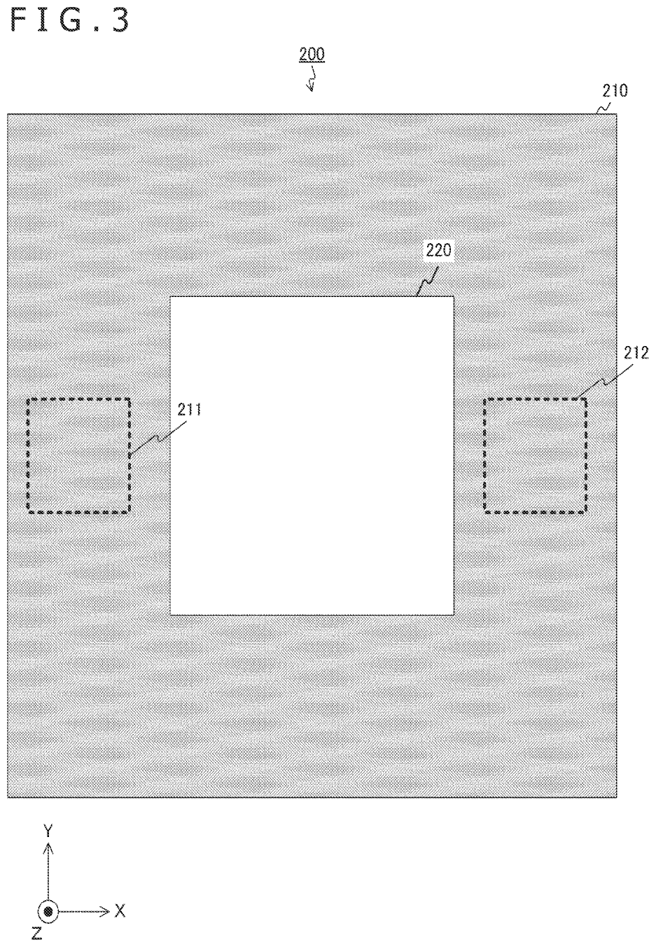

FIG. 3 is an exemplary plan view of the semiconductor package 200 according to the first embodiment of the present technology. As exemplified in FIG. 3, when seen from the Z-axis direction, the transparent member 220 is rectangular, and the embedding resin 210 having a rectangular periphery is formed around the transparent member 220. In the embedding resin 210, the embedded circuits 211 and 212 are embedded.

As exemplified in FIG. 3, the embedded circuits 211 and 212 are embedded in the embedding resin 210 around the transparent member 220, so that advanced functions can be achieved with the added circuits while an increase in size of the semiconductor package 200 is prevented.

Circuits can be added using the SiP technology, but the size of the semiconductor package is increased in that case. For example, a SiP including a semiconductor chip and an additional semiconductor chip that are arranged side by side has a larger semiconductor package area. Further, a SiP including a plurality of semiconductor chips stacked has a larger semiconductor package thickness.

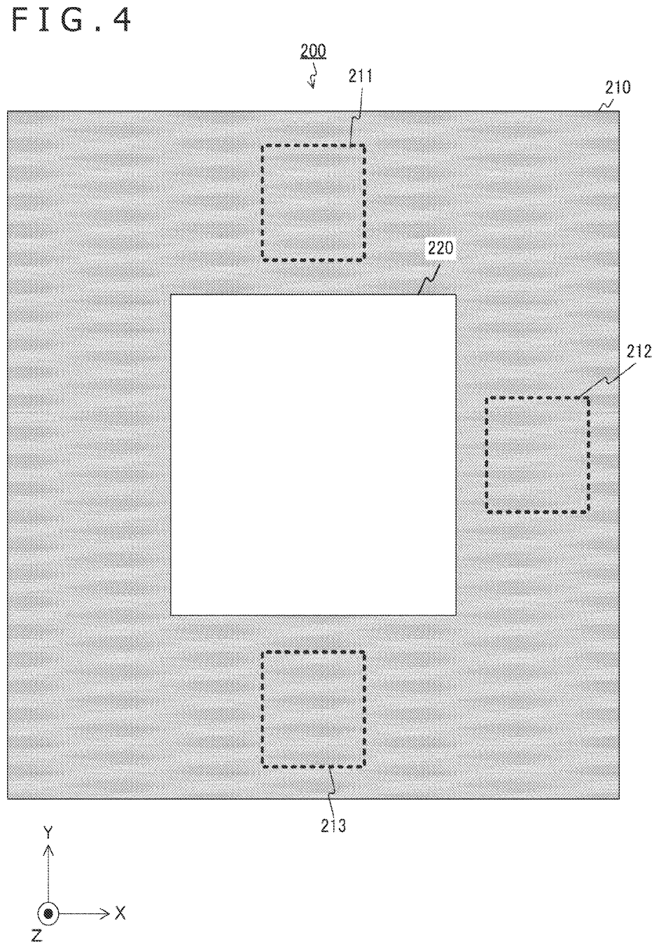

Note that, the two circuits, namely, the embedded circuits 211 and 212, are embedded, but the number of embedded circuits is not limited to two. For example, as exemplified in FIG. 4, an embedded circuit 213 can further be embedded in addition to the embedded circuits 211 and 212.

Next, a method of manufacturing the semiconductor package 200 is described.

### [Method of Manufacturing Semiconductor Package]

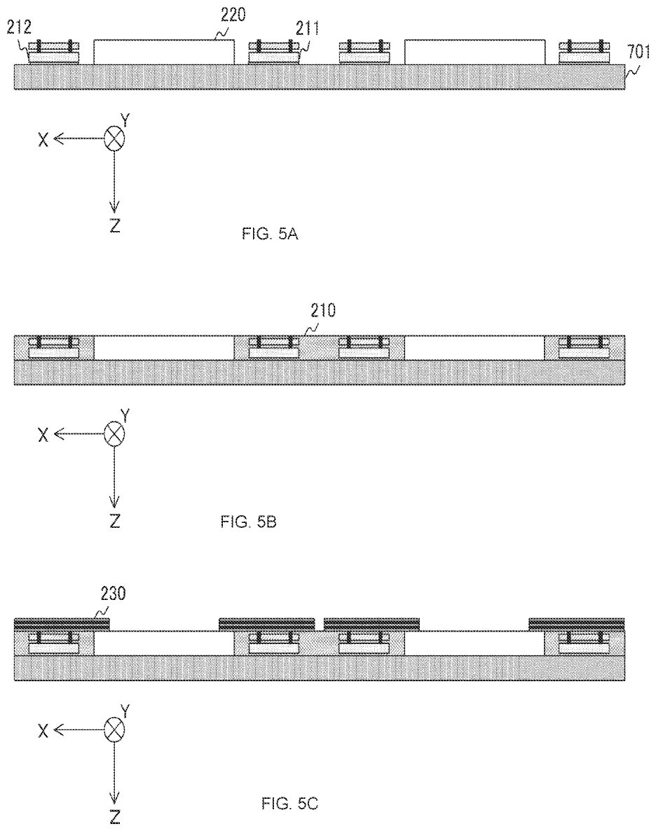

FIG. 5 depicts diagrams illustrating the manufacturing processes of the semiconductor package 200 up to the formation of the redistribution layer 230 according to the first embodiment of the present technology. Here, a of FIG. 5 is a diagram illustrating the process of placing the transparent member 220 and the embedded circuits 211 and 212 on a support substrate 701, b of FIG. 5 is a diagram illustrating the process of forming the embedding resin 210, and c of FIG. 5 is a diagram illustrating the process of forming the redistribution layer 230.

A system for manufacturing the semiconductor package 200 first places the support substrate 701. The support substrate 701 has a circular shape when seen from the Z direction, and has a surface divided into a plurality of rectangular chip areas. As exemplified in a of FIG. 5, the manufacturing system places the transparent member 220 on each chip area on the support substrate 701, and places the embedded circuits 211 and 212 around the transparent member 220.

Next, as exemplified in b of FIG. 5, the manufacturing system forms the embedding resin 210 around the transparent member 220 to embed the embedded circuits 211 and 212.

Subsequently, as exemplified in c of FIG. 5, the manufacturing system forms the redistribution layer 230.

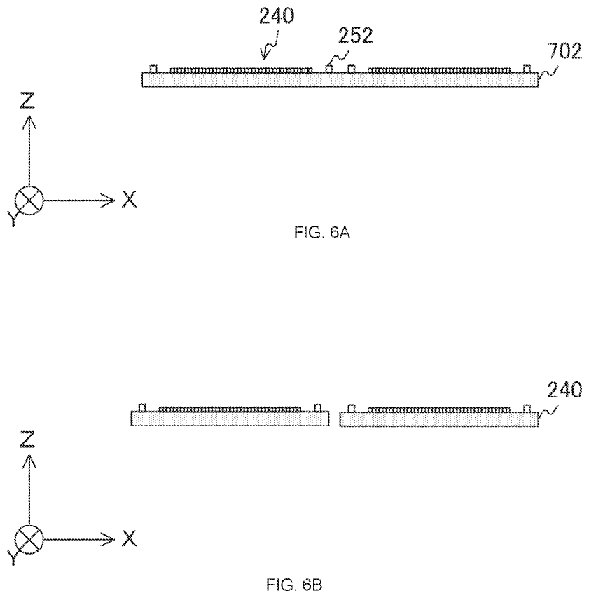

FIG. 6 depicts diagrams illustrating the manufacturing processes of the semiconductor package 200 up to the dicing of an image sensor wafer 702 according to the first embodiment of the present technology. Here, a of FIG. 6 is a diagram illustrating the process of forming the solid-state image pickup element 240 and the like on the image sensor wafer 702, and b of FIG. 6 is a diagram illustrating the process of dicing the image sensor wafer 702.

As exemplified in a of FIG. 6, the manufacturing system divides the surface of the image sensor wafer 702 into a plurality of rectangular chip areas, and forms the solid-state image pickup element 240 and the bumps 252 on each chip area. Next, as exemplified in b of FIG. 6, the manufacturing system singulates the image sensor wafer 702 by dicing in units of chip area.

The processes exemplified in FIG. 5 and the processes exemplified in FIG. 6 are executed in parallel. Note that the manufacturing system can also execute those processes sequentially.

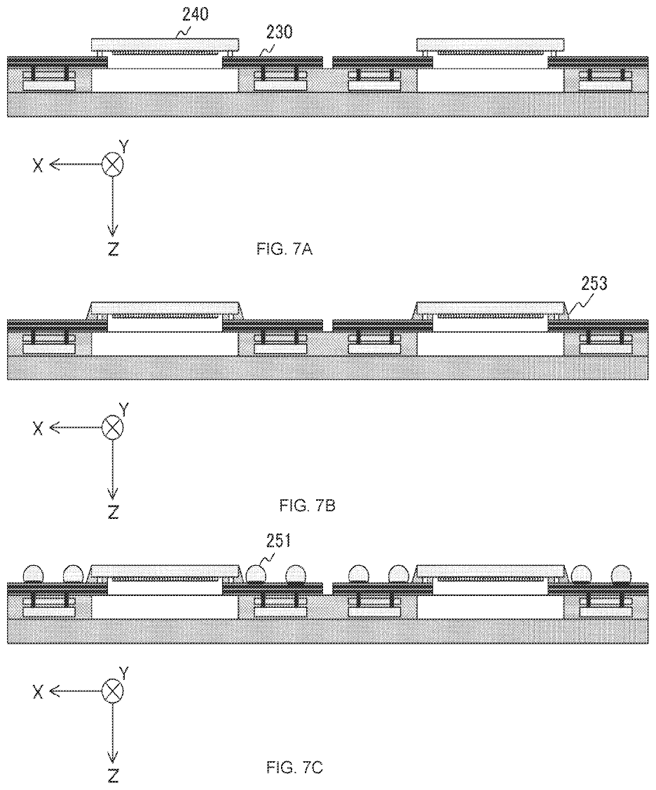

FIG. 7 depicts diagrams illustrating the manufacturing processes of the semiconductor package 200 up to the formation of the external terminals 251 according to the first embodiment of the present technology. Here, a of FIG. 7 is a diagram illustrating the process of flip chip connection, b of FIG. 7 is a diagram illustrating the process of applying the underfill material 253, and c of FIG. 7 is a diagram illustrating the process of mounting the external terminals 251.

As exemplified in a of FIG. 7, the manufacturing system connects the solid-state image pickup element 240 that has undergone singulation to the corresponding redistribution layer 230 by the bumps 252 (that is, flip chip connection).

Next, as exemplified in b of FIG. 7, the manufacturing system applies the underfill material 253 to the connection portion between the solid-state image pickup element 240 and the redistribution layer 230 to seal the connection portion.

Subsequently, as exemplified in c of FIG. 7, the manufacturing system mounts the predetermined number of external terminals 251 on the redistribution layer 230.

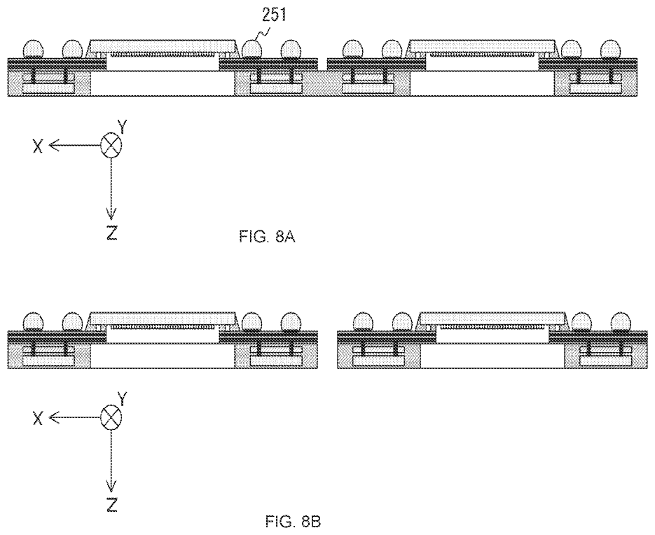

FIG. 8 depicts diagrams illustrating the processes up to dicing according to the first embodiment of the present technology. Here, a of FIG. 8 is a diagram illustrating the process of peeling off the support substrate 701, and b of FIG. 8 is a diagram illustrating the process of dicing.

As exemplified in a of FIG. 8, the manufacturing system peels off the support substrate 701 with heat, an ultraviolet ray, a laser, or the like. Next, as exemplified in b of FIG. 8, the manufacturing system singulates the wafer having implemented thereon the solid-state image pickup element 240 by dicing in units of chip area.

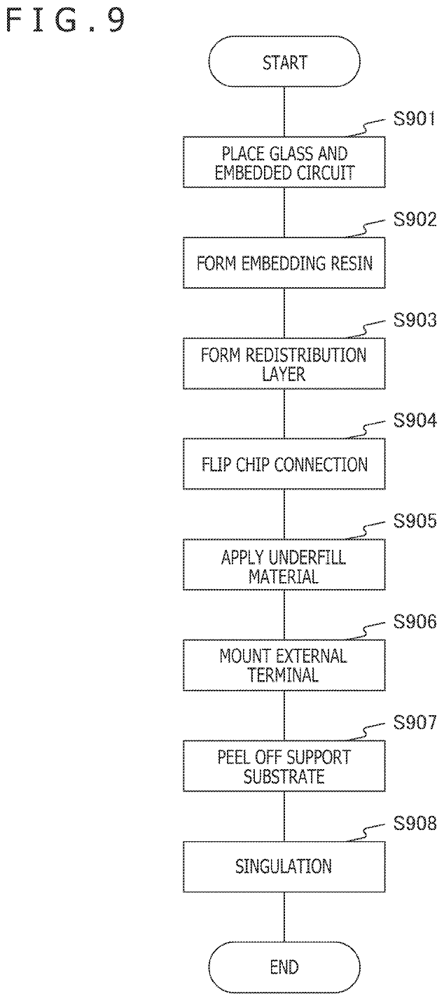

FIG. 9 is a flowchart illustrating an exemplary manufacturing process of the semiconductor package 200 according to the first embodiment of the present technology.

The system for manufacturing the semiconductor package 200 places the transparent member 220 on each chip area on the support substrate 701, and places the embedded circuits 211 and 212 around the transparent member 220 (Step S901). The manufacturing system forms the embedding resin 210 around the transparent member 220 (Step S902), and forms the redistribution layer 230 (Step S903).

Further, the manufacturing system singulates the image sensor wafer and connects the solid-state image pickup element 240 that has undergone singulation to the corresponding redistribution layer 230 by flip chip connection (Step S904).

Next, the manufacturing system applies the underfill material 253 to the connection portion between the solid-state image pickup element 240 and the redistribution layer 230 to seal the connection portion (Step S905), and mounts the external terminals 251 (Step S906). Subsequently, the manufacturing system peels off the support substrate 701 (Step S907), and singulates the wafer by dicing (Step S908). After Step S908, the manufacturing system executes an inspection process or the like as needed and ends the manufacturing process of the semiconductor package 200.

In such a way, according to the first embodiment of the present technology, the embedded circuits 211 and 212 are embedded in the embedding resin 210 formed around the transparent member 220, so that advanced functions can be achieved with the added circuits while an increase in package size is prevented.

### First Modified Example

In the first embodiment described above, the support substrate 701 is peeled off after the solid-state image pickup element 240 has been subjected to flip chip connection, but the support substrate 701 can also be peeled off before flip chip connection. A method of manufacturing the semiconductor package 200 according to a first modified example of the first embodiment is different from the first embodiment in that the support substrate 701 is peeled off before flip chip connection.

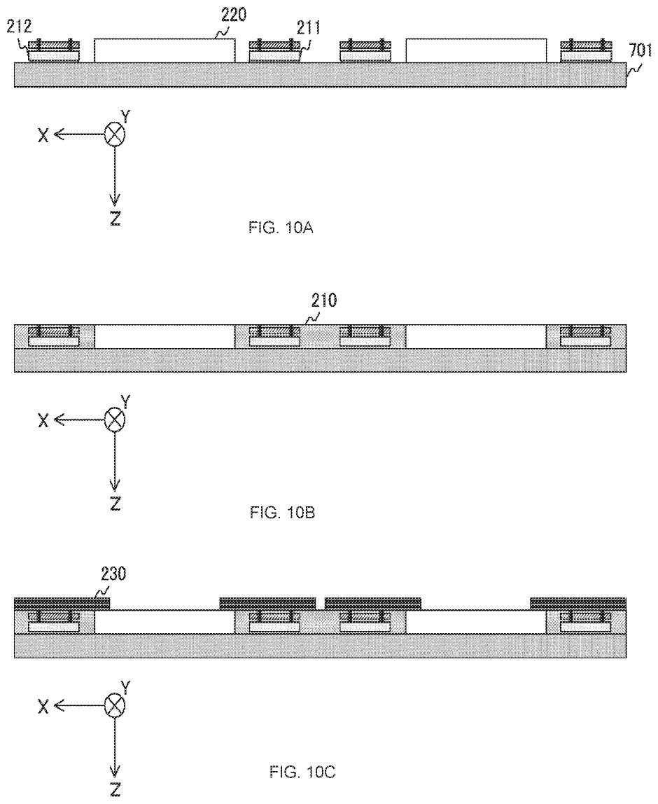

FIG. 10 depicts diagrams illustrating the manufacturing processes of the semiconductor package 200 up to the formation of the redistribution layer 230 according to the first modified example of the first embodiment of the present technology. Here, a of FIG. 10 is a diagram illustrating the process of placing the transparent member 220 and the embedded circuits 211 and 212 on the support substrate 701, b of FIG. 10 is a diagram illustrating the process of forming the embedding resin 210, and c of FIG. 10 is a diagram illustrating the process of forming the redistribution layer 230.

As exemplified in a of FIG. 10, the manufacturing system places the transparent member 220 on each chip area on the support substrate 701, and places the embedded circuits 211 and 212 around the transparent member 220. Next, the manufacturing system forms the embedding resin 210 around the transparent member 220 as exemplified in b of FIG. 10, and forms the redistribution layer 230 as exemplified in c of FIG. 10.

FIG. 11 depicts diagrams illustrating the manufacturing processes of the semiconductor package 200 up to the dicing of the image sensor wafer 702 according to the first modified example of the first embodiment of the present technology. Here, a of FIG. 11 is a diagram illustrating the process of peeling off the support substrate 701, b of FIG. 11 is a diagram illustrating the process of forming the solid-state image pickup element 240 and the like on the image sensor wafer 702, and c of FIG. 11 is a diagram illustrating the process of dicing the image sensor wafer 702.

As exemplified in a of FIG. 11, the manufacturing system peels off the support substrate 701. Further, as exemplified in b of FIG. 11, the manufacturing system forms the solid-state image pickup element 240 and the bumps 252 on the image sensor wafer 702. Next, as exemplified in c of FIG. 11, the manufacturing system singulates the image sensor wafer 702 by dicing in units of chip area.

The processes in FIG. 10 and a of FIG. 11 and the processes in b and c of FIG. 11 are executed in parallel. Note that the manufacturing system can also execute those processes sequentially. Further, the processes after the support substrate 701 has been peeled off are executed on a dicing sheet, for example.

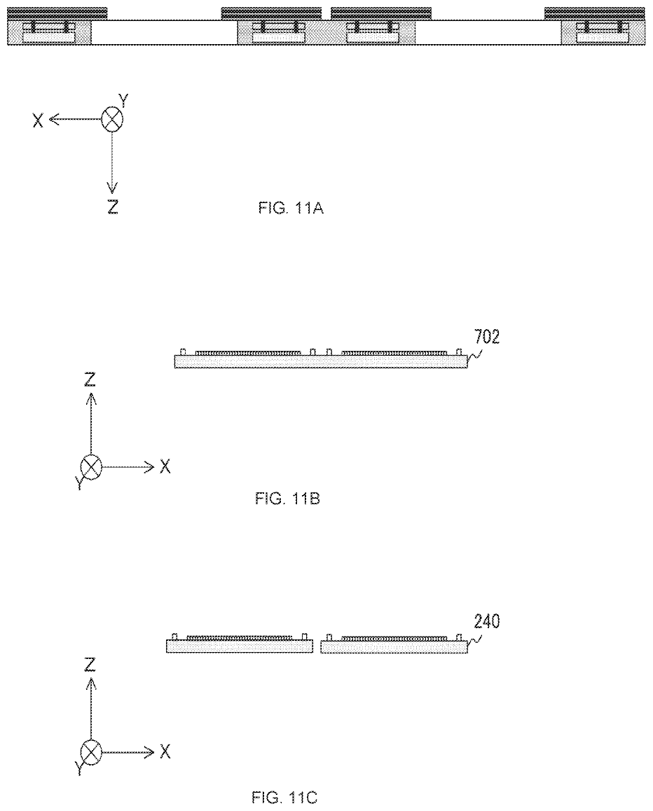

FIG. 12 depicts diagrams illustrating the manufacturing processes of the semiconductor package 200 up to the formation of the external terminals 251 according to the first modified example of the first embodiment of the present technology. Here, a of FIG. 12 is a diagram illustrating the process of flip chip connection, b of FIG. 12 is a diagram illustrating the process of applying the underfill material 253, and c of FIG. 12 is a diagram illustrating the process of mounting the external terminals 251.

As exemplified in a of FIG. 12, the manufacturing system performs flip chip connection on the solid-state image pickup element 240 that has undergone singulation. Next, as exemplified in b of FIG. 12, the manufacturing system applies the underfill material 253 to the connection portion between the solid-state image pickup element 240 and the redistribution layer 230 to seal the connection portion. Subsequently, as exemplified in c of FIG. 12, the manufacturing system mounts the predetermined number of external terminals 251 on the redistribution layer 230.

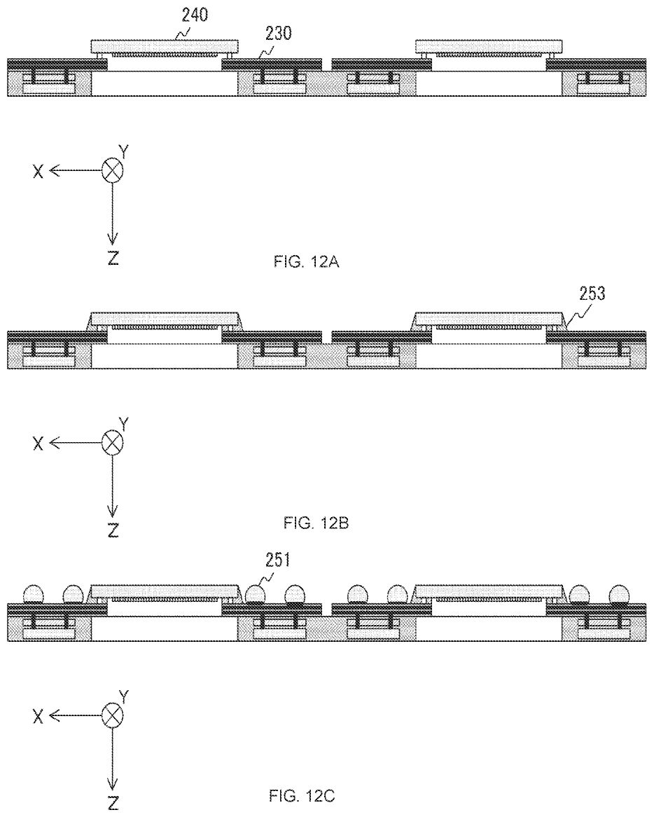

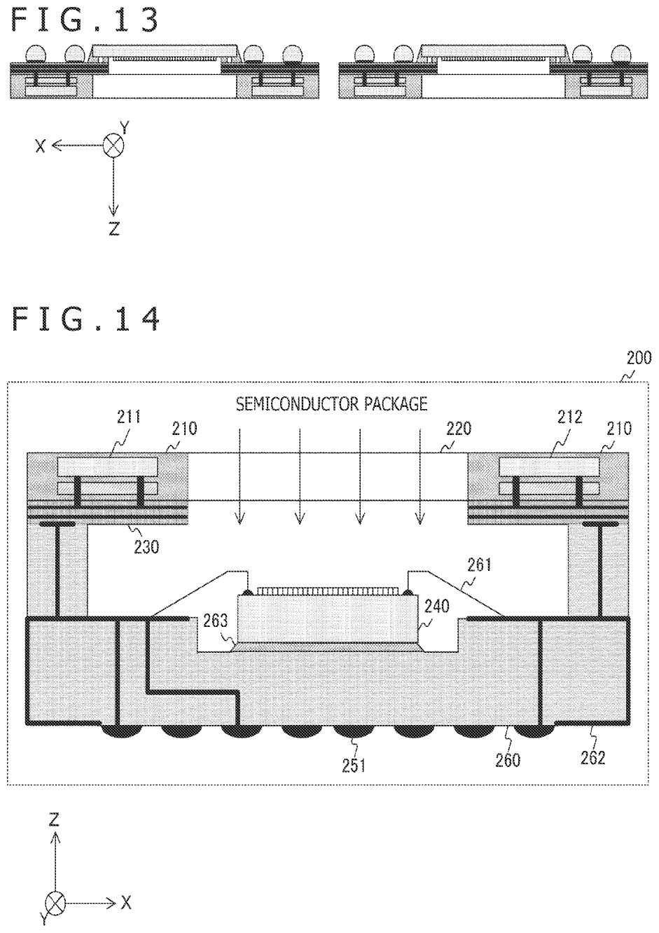

FIG. 13 is a diagram illustrating the process of dicing according to the first modified example of the first embodiment of the present technology. As exemplified in FIG. 13, the manufacturing system singulates the wafer having implemented thereon the solid-state image pickup element 240, by dicing in units of chip area.

In such a way, according to the first modified example of the first embodiment of the present technology, the support substrate 701 is peeled off before flip chip connection, so that the procedure of peeling off the support substrate 701 immediately before dicing can be omitted.

### Second Modified Example

In the first embodiment described above, the embedded circuits 211 and 212 are embedded around the transparent member 220 in the FOWLP, and the technology of embedding the embedded circuits 211 and 212 can also be applied to a ceramic package. The semiconductor package 200 according to a second modified example of the first embodiment is different from that of the first embodiment in that the embedded circuits 211 and 212 are embedded around the transparent member 220 in a ceramic package.

FIG. 14 is a sectional view illustrating a configuration example of the semiconductor package 200 according to the second modified example of the first embodiment of the present technology. As exemplified in FIG. 14, the semiconductor package 200 according to the second modified example of the first embodiment is different from that of the first embodiment in that a ceramic substrate 260 is included in place of the bumps 252 and the underfill material 253.

The ceramic substrate 260 is a ceramic substrate having formed therein a recess. In the ceramic substrate 260, a predetermined number of signal lines 262 are wired. Further, the solid-state image pickup element 240 is provided in the recess and connected with the signal lines 262 and wires 261. When the light receiving-side surface of the solid-state image pickup element 240 is the upper surface, the lower surface of the solid-state image pickup element 240 is adhered to the ceramic substrate 260 with an adhesive 263. The external terminals 251 are disposed on the lower surface of the ceramic substrate 260.

Further, the recess in the ceramic substrate 260 is sealed with the transparent member 220 and the redistribution layer 230. The sealed space is called a “cavity.”

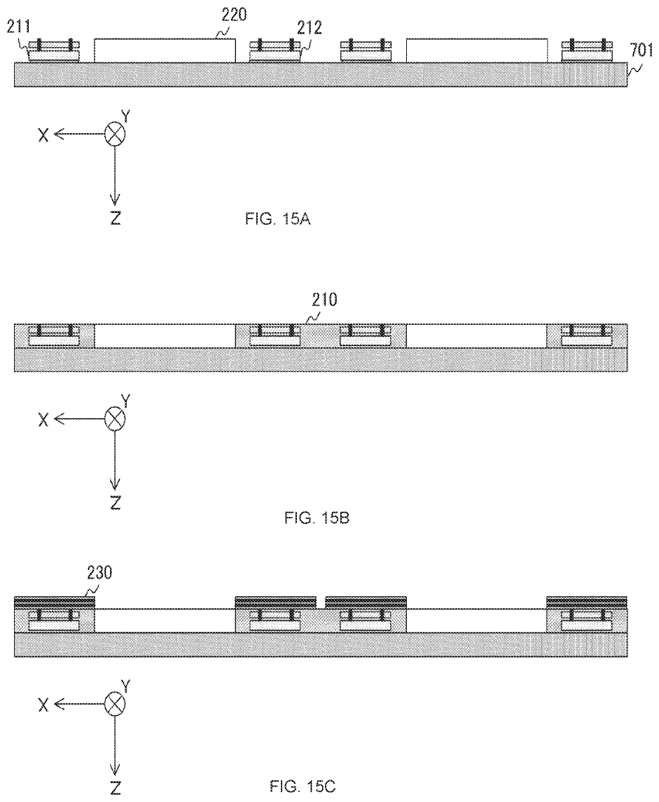

FIG. 15 depicts diagrams illustrating the manufacturing processes of the semiconductor package 200 up to the formation of the redistribution layer 230 according to the second modified example of the first embodiment of the present technology. Here, a of FIG. 15 is a diagram illustrating the process of placing the transparent member 220 and the embedded circuits 211 and 212 on the support substrate 701, b of FIG. 15 is a diagram illustrating the process of forming the embedding resin 210, and c of FIG. 15 is a diagram illustrating the process of forming the redistribution layer 230.

As exemplified in a of FIG. 15, the manufacturing system places the transparent member 220 on each chip area on the support substrate 701, and places the embedded circuits 211 and 212 around the transparent member 220. Next, the manufacturing system forms the embedding resin 210 around the transparent member 220 as exemplified in b of FIG. 15, and forms the redistribution layer 230 as exemplified in c of FIG. 15.

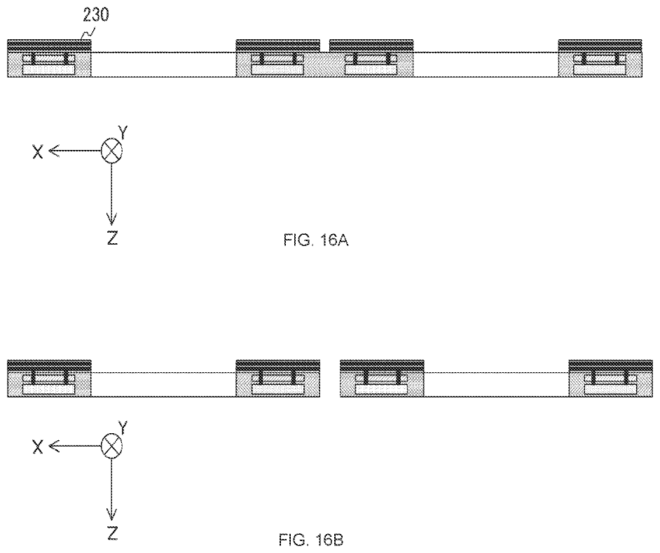

FIG. 16 depicts diagrams illustrating the manufacturing processes of the semiconductor package 200 up to dicing according to the second modified example of the first embodiment of the present technology. Here, a of FIG. 16 is a diagram illustrating the process of peeling off the support substrate 701, and b of FIG. 16 is a diagram illustrating the process of dicing.

The manufacturing system peels off the support substrate 701 as exemplified in a of FIG. 16, and performs singulation by dicing as exemplified in b of FIG. 16.

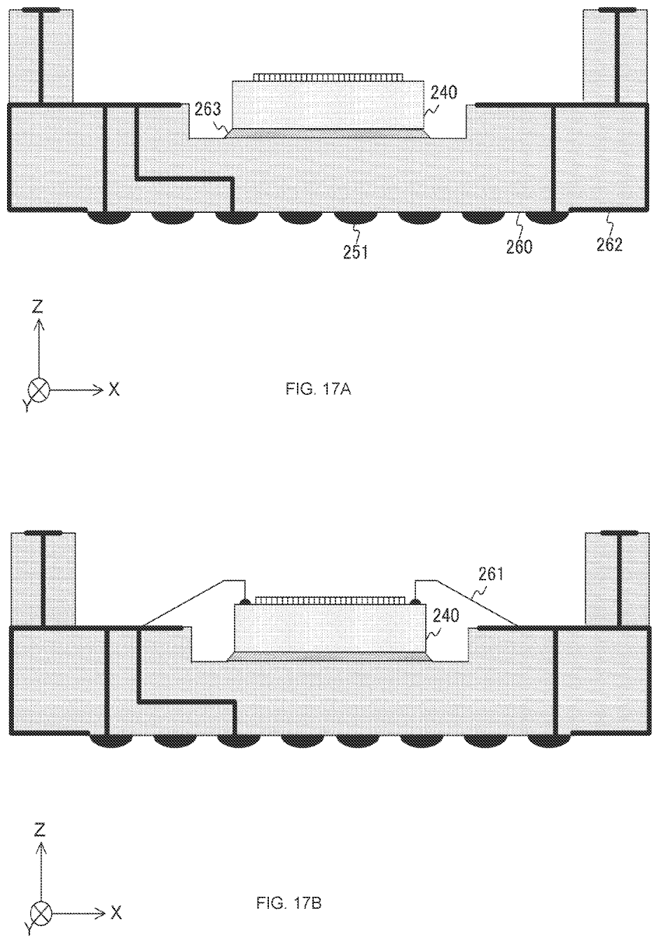

FIG. 17 depicts diagrams illustrating the manufacturing processes of the semiconductor package 200 up to wire bonding according to the second modified example of the first embodiment of the present technology. Here, a of FIG. 17 is a diagram illustrating the process of adhering the solid-state image pickup element 240 to the ceramic substrate 260, and b of FIG. 17 is a diagram illustrating the process of wire bonding.

As exemplified in a of FIG. 17, the manufacturing system adheres the solid-state image pickup element 240 to the ceramic substrate 260, which is a silicon die, with the adhesive 263. Then, as exemplified in b of FIG. 17, the manufacturing system connects the solid-state image pickup element 240 to the ceramic substrate 260 with the wires 261 (that is, performs wire bonding).

Then, the manufacturing system seals the recess in the ceramic substrate 260 with the members that have undergone singulation in the process in FIG. 16 (that is, the transparent member 220, the embedding resin 210, and the redistribution layer 230).

The processes exemplified in FIG. 16 and the processes exemplified in FIG. 17 are executed in parallel. Note that the manufacturing system can also execute those processes sequentially.

In such a way, according to the second modified example of the first embodiment of the present technology, the embedded circuits 211 and 212 are embedded around the transparent member 220 in the ceramic package, so that advanced functions can be achieved while an increase in size of the ceramic package is prevented.

### Third Modified Example

In the first embodiment described above, while the embedded circuits 211 and 212 are embedded in the embedding resin 210 around the transparent member 220, these circuits sometimes generate heat when operating. Further, there is also a risk that the strength of the semiconductor package 200 is insufficient. The semiconductor package 200 according to a third modified example of the first embodiment is different from that of the first embodiment in that the heat release property is enhanced and a frame 270 for reinforcement is provided.

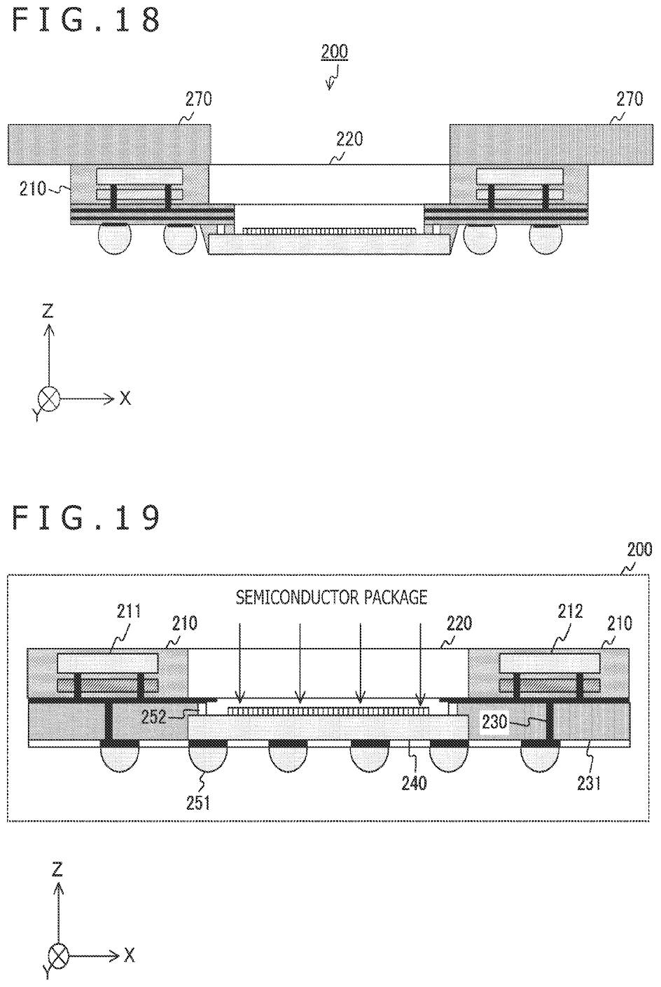

FIG. 18 is a sectional view illustrating a configuration example of the semiconductor package 200 according to the third modified example of the first embodiment of the present technology. The semiconductor package 200 according to the third modified example of the first embodiment is different from that of the first embodiment in that the frame 270 is further included.

The frame 270 is a member having formed therein an opening portion when seen from the Z direction, and the shape and area of the opening portion are substantially the same as those of the transparent member 220. As the material of the frame 270, a material more thermally conductive and rigid than the embedding resin 210 (copper, aluminum, or the like) is used. The frame 270 is laminated on the light receiving-side surface of the embedding resin 210.

With the laminated metal frame 270, the heat release property is enhanced, and the semiconductor package 200 is thus reinforced. Note that the first modified example or the second modified example is applicable to the third modified example of the first embodiment.

In such a way, according to the third modified example of the first embodiment of the present technology, the metal frame 270 is laminated on the embedding resin 210, so that the heat release property of the semiconductor package 200 can be enhanced and the semiconductor package 200 can thus be reinforced.

### 2. Second Embodiment

In the first embodiment described above, the external terminals 251 are provided in the fan-out area, but, in this configuration, the external terminals 251 may be insufficient in number in some cases. The semiconductor package 200 of a second embodiment is different from that of the first embodiment in that the external terminals 251 are provided also in a fan-in area.

FIG. 19 is a sectional view illustrating a configuration example of the semiconductor package 200 according to the second embodiment of the present technology. The redistribution layer 230 of the second embodiment is formed around the solid-state image pickup element 240 when seen from the Z direction. Further, TMVs (Through Mold Vias) 231 are formed in the redistribution layer 230. In the fan-out area, the external terminals 251 are connected to the TMVs 231. Further, when the light receiving-side surface of the semiconductor package 200 is the upper surface, the redistribution layer 230 is formed on the lower surface of the semiconductor package 200, and the external terminals 251 are also provided under the solid-state image pickup element 240. The area under the solid-state image pickup element 240 is called a fan-in area.

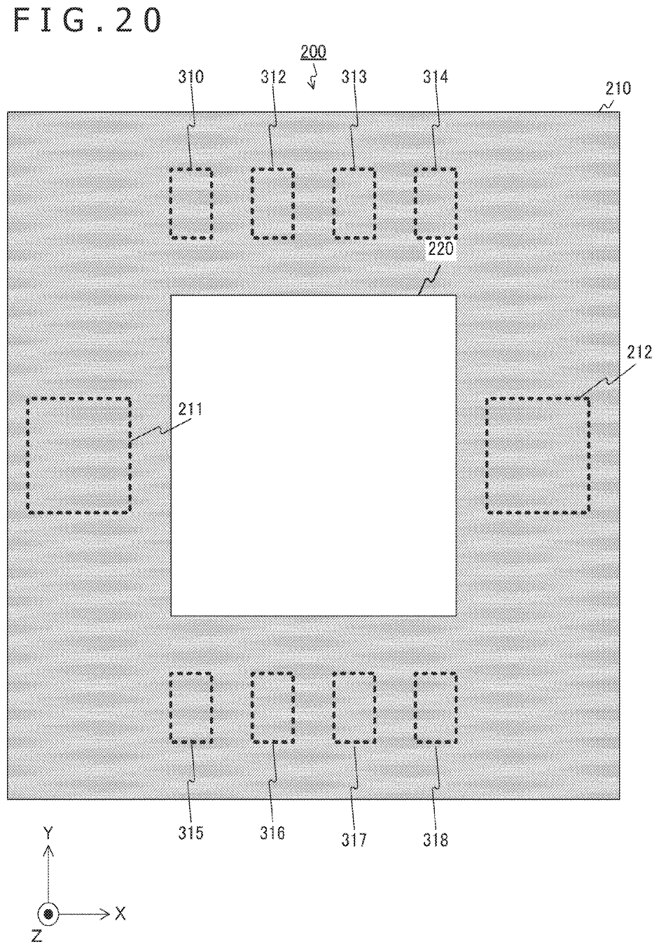

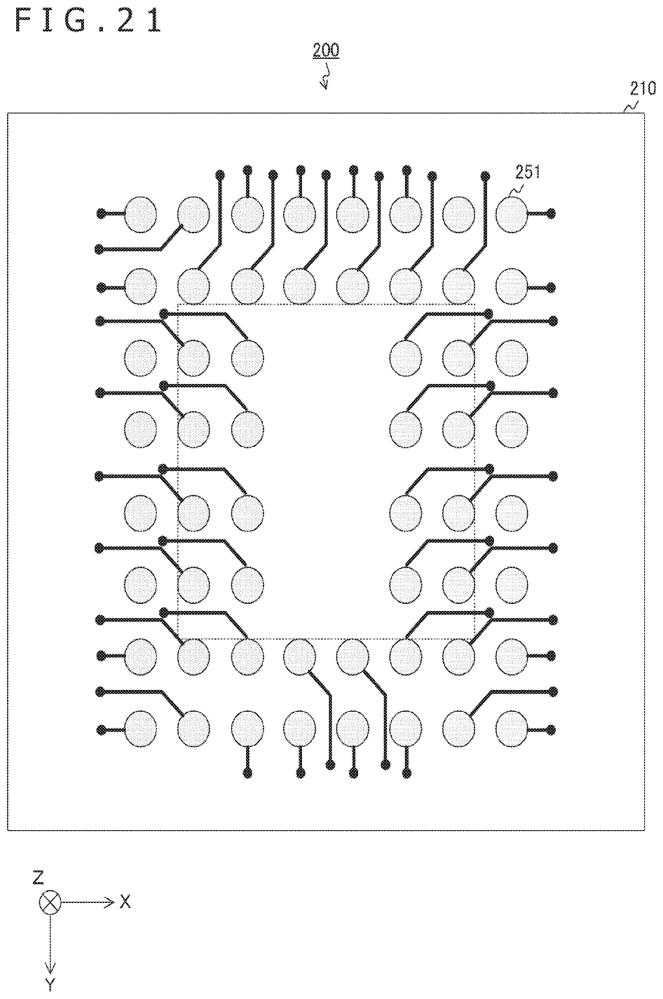

FIG. 20 is an exemplary top view of the semiconductor package 200 according to the second embodiment of the present technology. As exemplified in FIG. 20, in the embedding resin 210, passive components 310 to 318 are further embedded, in addition to the embedded circuits 211 and 212.

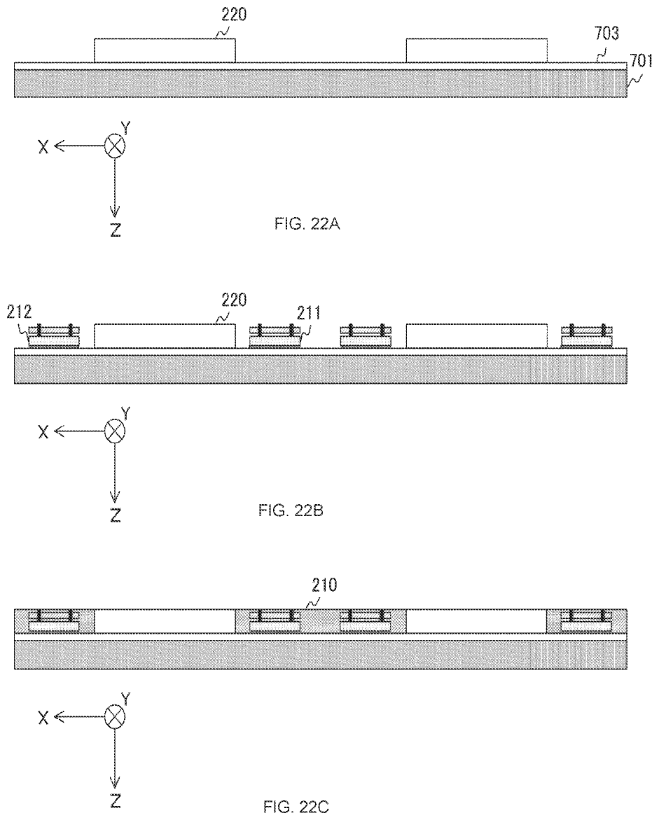

FIG. 21 is an exemplary bottom view of the semiconductor package 200 according to the second embodiment of the present technology. The area surrounded by the dotted line in FIG. 21 corresponds to the fan-in area. Further, the area around the fan-in area corresponds to the fan-out area. As exemplified in FIG. 21, the external terminals 251 are also disposed in the fan-in area in addition to the fan-out area.

FIG. 22 depicts diagrams illustrating the manufacturing processes of the semiconductor package up to the embedding of the circuits according to the second embodiment of the present technology. Here, a of FIG. 22 is a diagram illustrating the process of placing the transparent member 220 on the support substrate 701, b of FIG. 22 is a diagram illustrating the process of placing the embedded circuits 211 and 212 on the support substrate 701, and c of FIG. 22 is a diagram illustrating the process of forming the embedding resin 210.

The manufacturing system places the transparent member 220 on each chip area on the support substrate 701 as exemplified in a of FIG. 22, and places the embedded circuits 211 and 212 around the transparent member 220 as exemplified in b of FIG. 22. Then, as exemplified in c of FIG. 22, the manufacturing system forms the embedding resin 210 around the transparent member 220 to embed the embedded circuits 211 and 212 in the embedding resin 210.

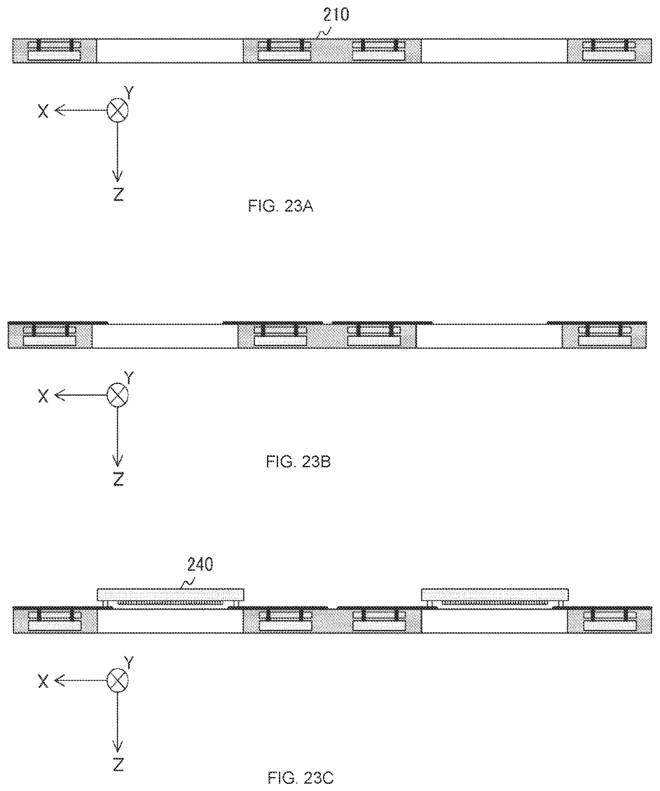

FIG. 23 depicts diagrams illustrating the manufacturing processes of the semiconductor package up to flip chip connection according to the second embodiment of the present technology. Here, a of FIG. 23 is a diagram illustrating the process of peeling off the support substrate 701, b of FIG. 23 is a diagram illustrating the wiring process of a redistribution line, and c of FIG. 23 is a diagram illustrating the process of flip chip connection.

The manufacturing system peels off the support substrate as exemplified in a of FIG. 23, and wires a signal line (redistribution line) as exemplified in b of FIG. 23. Then, as exemplified in c of FIG. 23, the manufacturing system performs flip chip connection on the solid-state image pickup element 240.

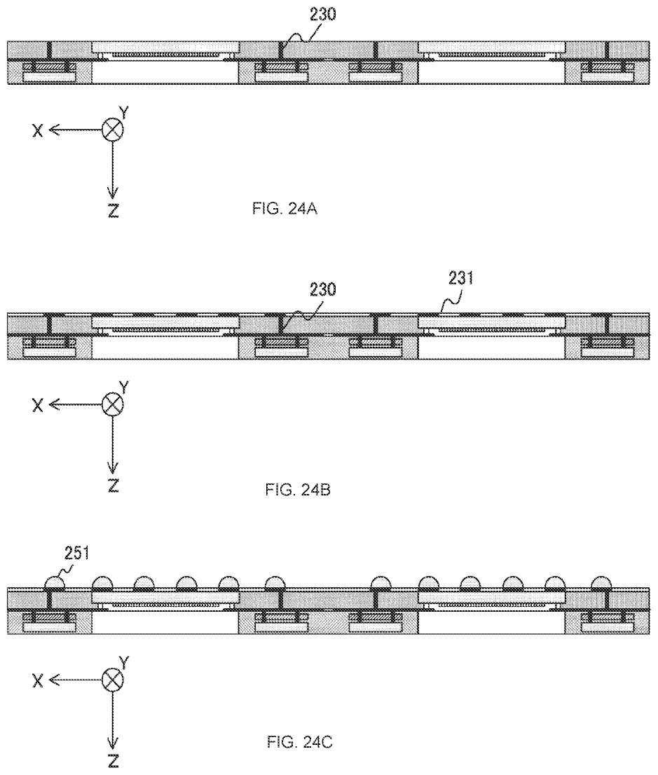

FIG. 24 depicts diagrams illustrating the manufacturing processes of the semiconductor package 200 up to the formation of the external terminals according to the second embodiment of the present technology. Here, a of FIG. 24 is a diagram illustrating the process of forming the TMVs 230, b of FIG. 24 is a diagram illustrating the process of forming the redistribution layer 231, and c of FIG. 24 is a diagram illustrating the process of mounting the external terminals 251.

The manufacturing system forms the TMVs 230 around the solid-state image pickup element 240 as exemplified in a of FIG. 24, and forms the redistribution layer 231 in the redistribution layer 230 as exemplified in b of FIG. 24. Then, as exemplified in c of FIG. 24, the manufacturing system mounts the external terminals 251 in the fan-in area and the fan-out area.

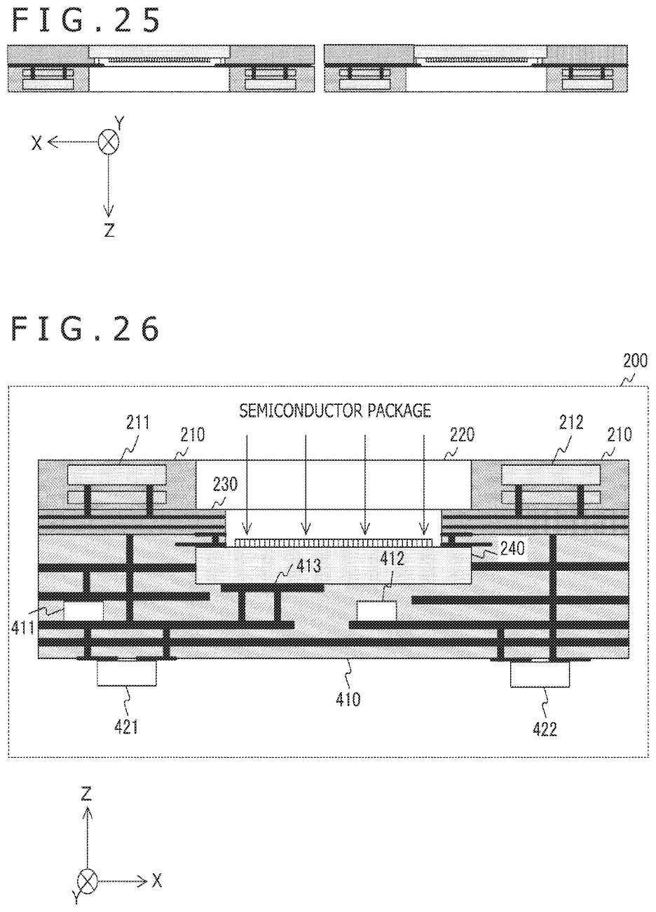

FIG. 25 is a diagram illustrating the process of dicing according to the second embodiment of the present technology. As exemplified in FIG. 25, the manufacturing system performs singulation by dicing.

In such a way, according to the second embodiment of the present technology, the external terminals 251 are also disposed in the fan-in area in addition to the fan-out area, so that the number of external terminals 251 to be disposed can be larger than that in the case where the external terminals 251 are disposed only in the fan-in area.

### 3. Third Embodiment

In the first embodiment described above, the process of forming the redistribution layer 230, the process of implementing the solid-state image pickup element 240, and the like are performed sequentially to manufacture the semiconductor package 200. The first embodiment, however, has a difficulty in reducing manufacturing lead time and cost. The semiconductor package 200 of a third embodiment is different from that of the first embodiment in that a plurality of layers are laminated and subjected to thermocompression bonding to manufacture the semiconductor package 200 at once.

FIG. 26 is a sectional view illustrating a configuration example of the semiconductor package 200 according to the third embodiment of the present technology. The semiconductor package 200 of the third embodiment includes a laminate substrate 410 in place of the bumps 252 and the underfill material 253.

The laminate substrate 410 is a laminate of a plurality of base materials. The solid-state image pickup element 240 is provided in the laminate substrate 410. Further, in the laminate substrate 410, incorporated components 411 and 412, such as resistors or capacitors, are incorporated and a signal line 413 is wired. Further, when the light receiving-side surface of the laminate substrate 410 is the upper surface, implemented components 421 and 422 are implemented on the lower surface of the laminate substrate 410. Note that, the laminate substrate 310, which incorporates the incorporated components 411 and 412, may include no incorporated component.

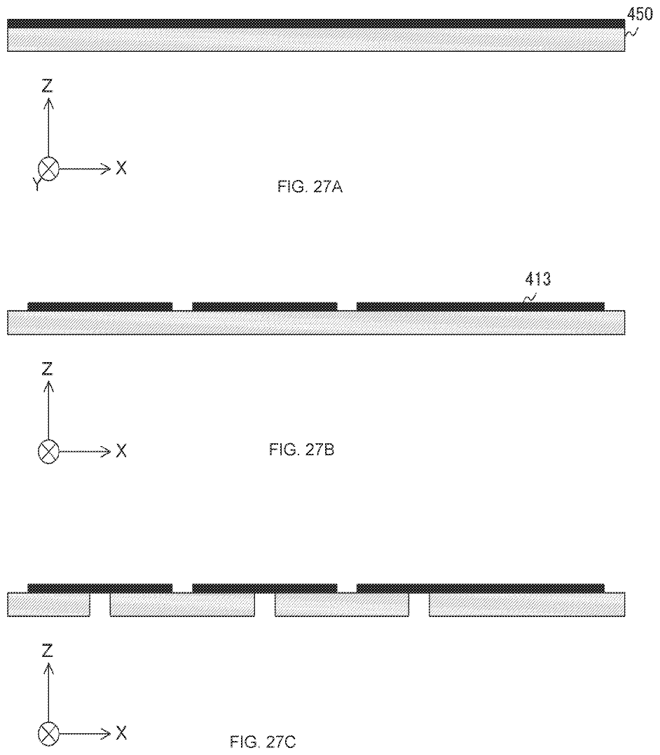

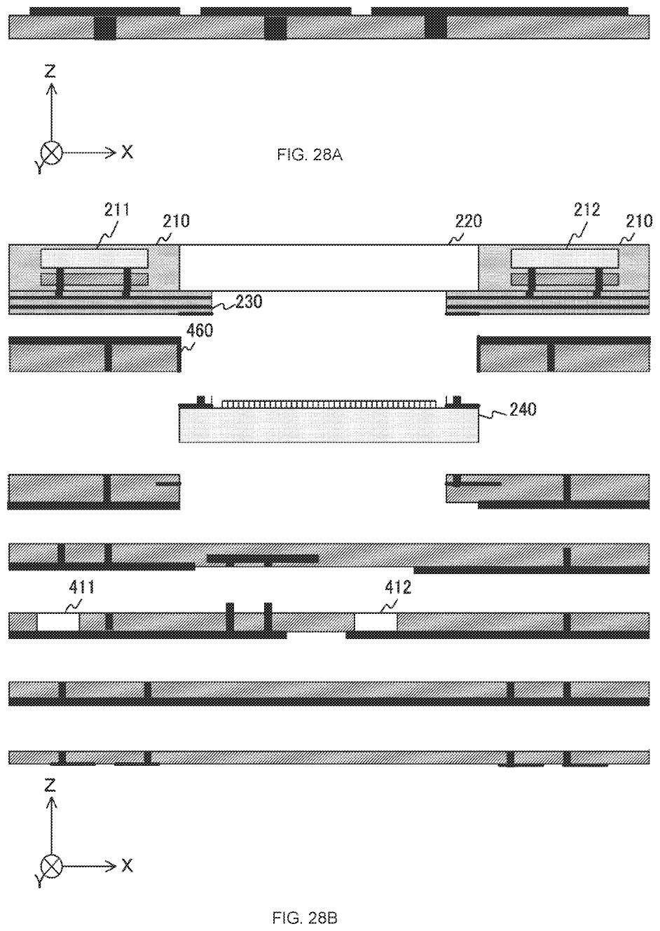

FIG. 27 depicts diagrams illustrating the manufacturing processes of the semiconductor package up to the formation of holes according to the third embodiment of the present technology. Here, a of FIG. 27 is a diagram illustrating the process of forming a conductive film, b of FIG. 27 is a diagram illustrating the process of etching, and c of FIG. 27 is a diagram illustrating the process of forming holes.

As exemplified in a of FIG. 27, the manufacturing system prepares a thermoplastic resin (such as liquid crystal polymer), an epoxy resin, or the like as a base material 450, and forms a conductive film on the surface of the base material 450. Then, as exemplified in b of FIG. 27, the manufacturing system processes the conductive film by etching to form the signal line 413. Subsequently, the manufacturing system forms holes in the base material 450 by a laser or the like as exemplified in c of FIG. 27.

FIG. 28 depicts diagrams illustrating the manufacturing processes of the semiconductor package up to lay-up according to the third embodiment of the present technology. Here, a of FIG. 28 is a diagram illustrating the process of filling using conductive paste, and b of FIG. 28 is a diagram illustrating the process of lay-up.

As exemplified in a of FIG. 28, the manufacturing system fills the holes formed by a laser or the like with conductive paste (such as solder paste).

Further, the manufacturing system manufactures a plurality of base materials by a similar manufacturing process. Of those base materials, in a base material 460, an opening portion with a smaller area than the solid-state image pickup element 240 is formed, and vias for connection with the solid-state image pickup element 240 are formed around the opening portion. Further, by a method similar to that in the first embodiment, a composite material including the transparent member 220 and the embedding resin 210 is formed.

As exemplified in b of FIG. 28, the manufacturing system lays up the composite material, the plurality of base materials, the redistribution layer 230, and the solid-state image pickup element 240 from the bottom.

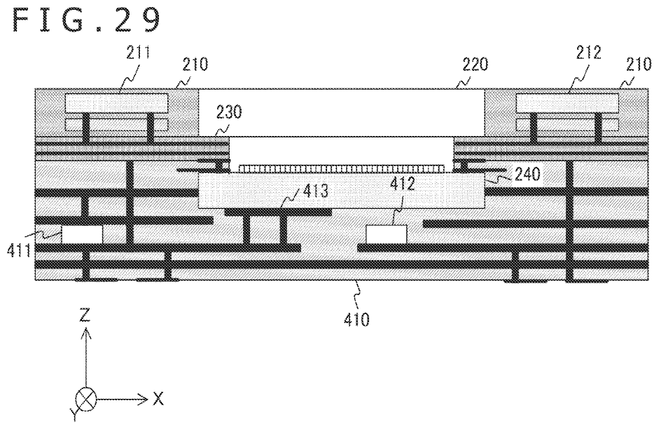

FIG. 29 is a diagram illustrating the process of pressing layers together according to the third embodiment of the present technology. As exemplified in FIG. 29, the manufacturing system heats the plurality of laid up layers and presses the layers together (that is, performs thermocompression bonding). With this thermocompression bonding, the vias in the base material are joined to the solid-state image pickup element 240. The plurality of layers are laminated and subjected to thermocompression bonding, so that reductions in manufacturing lead time and cost of the semiconductor package 200 can be achieved.

In such a way, according to the third embodiment of the present technology, the plurality of layers including the solid-state image pickup element 240 and the like are laminated and subjected to thermocompression bonding, so that the manufacturing process of the semiconductor package 200 can be simplified.

### 4. Fourth Embodiment

In the first embodiment described above, the solid-state image pickup element 240 is sealed with the transparent member 220, but there is a risk that, if moisture is contained in the sealed space, the transparent member 220 fogs up when the moisture is condensed due to a temperature drop. The semiconductor package 200 of a fourth embodiment is different from that of the first embodiment in that humidity is measured and the transparent member 220 is heated when the humidity exceeds a threshold.

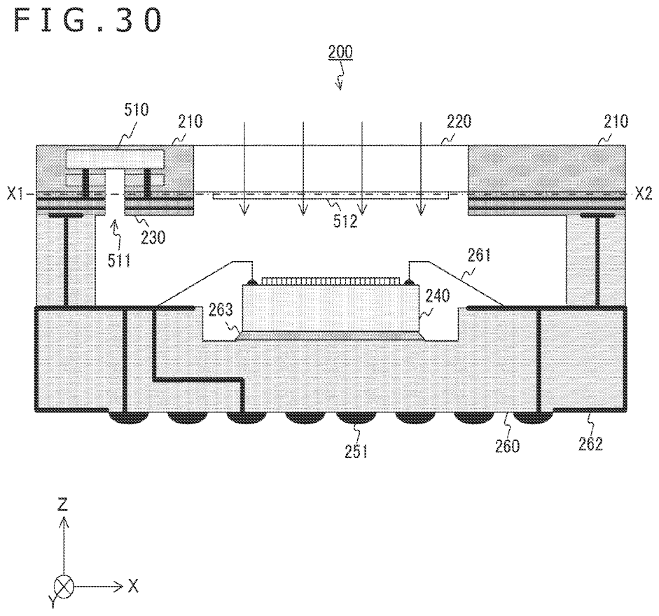

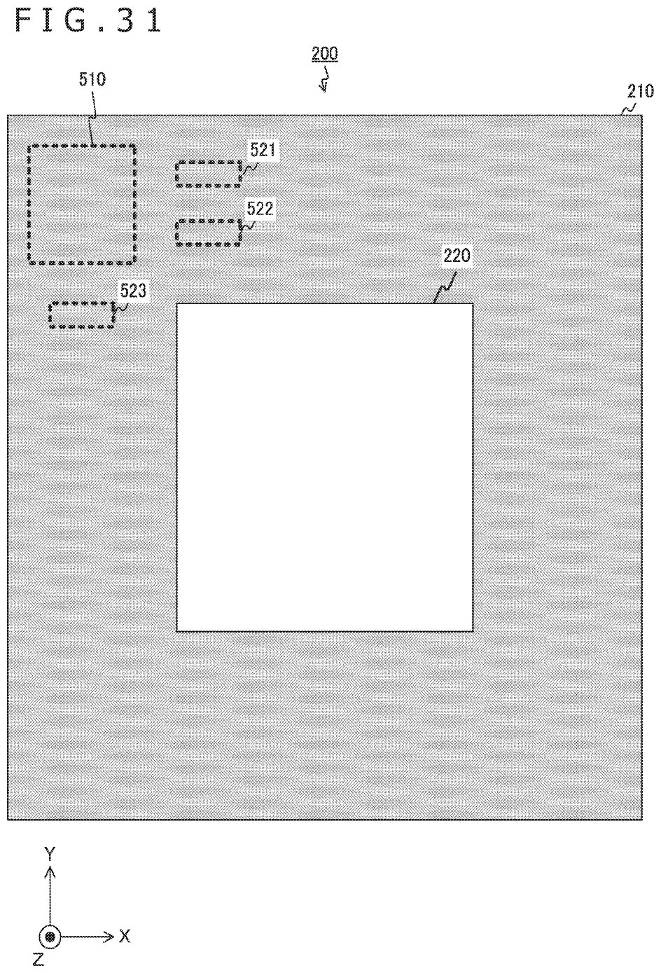

FIG. 30 is a sectional view illustrating a configuration example of the semiconductor package 200 according to the fourth embodiment of the present technology. The semiconductor package 200 of the fourth embodiment includes a humidity sensor 510 in place of the embedded circuits 211 and 212. Further, in the embedding resin 210 and the redistribution layer 230, a measurement hole 511 that extends from the cavity to the humidity sensor 510 is formed. Further, when the light receiving-side surface of the transparent member 220 is the upper surface, a heater 512 is formed on the lower surface of the transparent member 220.

Further, the semiconductor package 200 of the fourth embodiment includes the ceramic substrate 260 in place of the bumps 252 and the underfill material 253. The configuration of the ceramic substrate 260 of the fourth embodiment is similar to that of the second modified example of the first embodiment exemplified in FIG. 14.

The humidity sensor 510 measures humidity in the recess in the ceramic substrate 260 (that is, cavity) through the measurement hole 511 and detects whether the humidity exceeds a predetermined threshold or not. The humidity sensor 510 supplies the detection result to the heater 512. The heater 512 heats the transparent member 220 when the humidity exceeds the threshold. With heating by the heater 512, the transparent member 220 can be prevented from fogging up due to condensation caused by a humidity rise.

FIG. 31 is an exemplary top view of the semiconductor package 200 according to the fourth embodiment of the present technology. As exemplified in FIG. 31, in the embedding resin 210 around the transparent member 220, the humidity sensor 510 and passive components 521, 522, and 523, such as resistors or capacitors, are embedded. Note that, the humidity sensor 510 and the passive components 521, 522, and 523 are examples of an embedded circuit described in the claims.

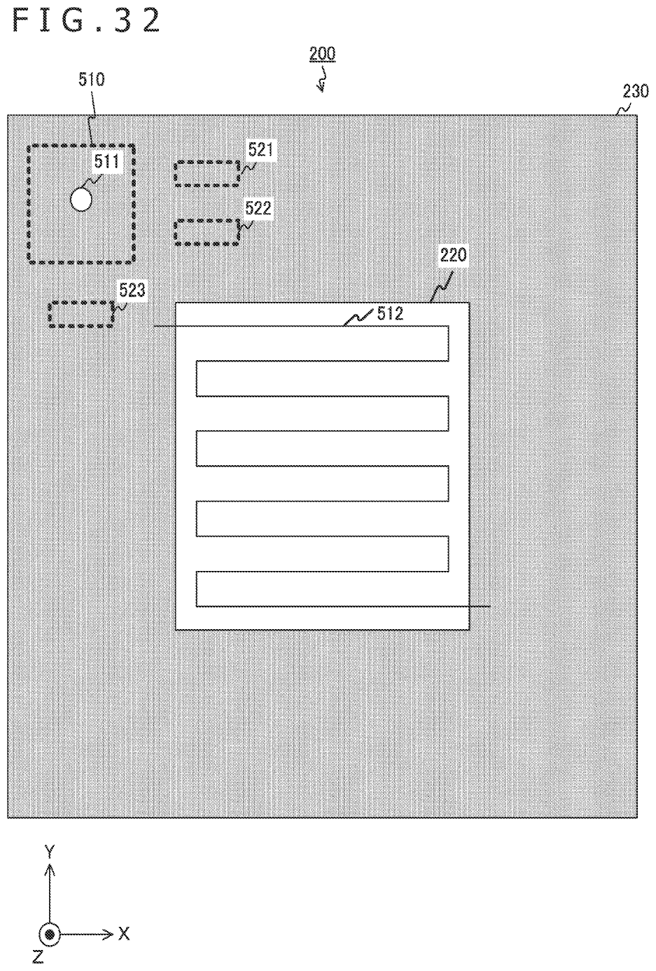

FIG. 32 is an exemplary sectional view of the semiconductor package 200 according to the fourth embodiment of the present technology. FIG. 32 is a sectional view of the semiconductor package 200 taken along the line X1-X2 of FIG. 30. As exemplified in FIG. 32, the measurement hole 511 is formed in the portion of the redistribution layer 230 that is under the humidity sensor 510. Further, the heater 512 is formed under the transparent member 220. As the heater 512, for example, transparent wiring is used. With the use of the transparent wiring, a drop in translucency can be prevented.

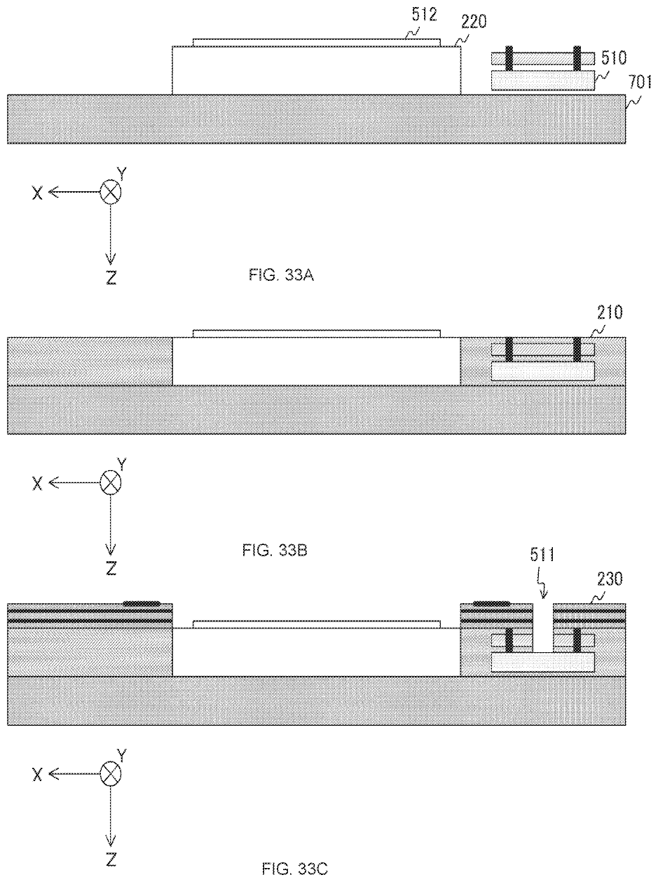

FIG. 33 depicts diagrams illustrating the manufacturing processes of the semiconductor package 200 up to the formation of the measurement hole 511 according to the fourth embodiment of the present technology. Here, a of FIG. 33 is a diagram illustrating the process of placing the transparent member 220 and the humidity sensor 510 on the support substrate 701, b of FIG. 33 is a diagram illustrating the process of forming the embedding resin 210, and c of FIG. 33 is a diagram illustrating the process of forming the redistribution layer 230 and the measurement hole 511.

As exemplified in a of FIG. 33, the manufacturing system places the transparent member 220 on each chip area on the support substrate 701, and places the humidity sensor 510 around the transparent member 220. Next, as exemplified in b of FIG. 33, the manufacturing system forms the embedding resin 210 around the transparent member 220 to embed the humidity sensor 510. As exemplified in c of FIG. 33, the manufacturing system forms the redistribution layer 230, and forms the measurement hole 511 that goes through the redistribution layer 230 and the embedding resin 210.

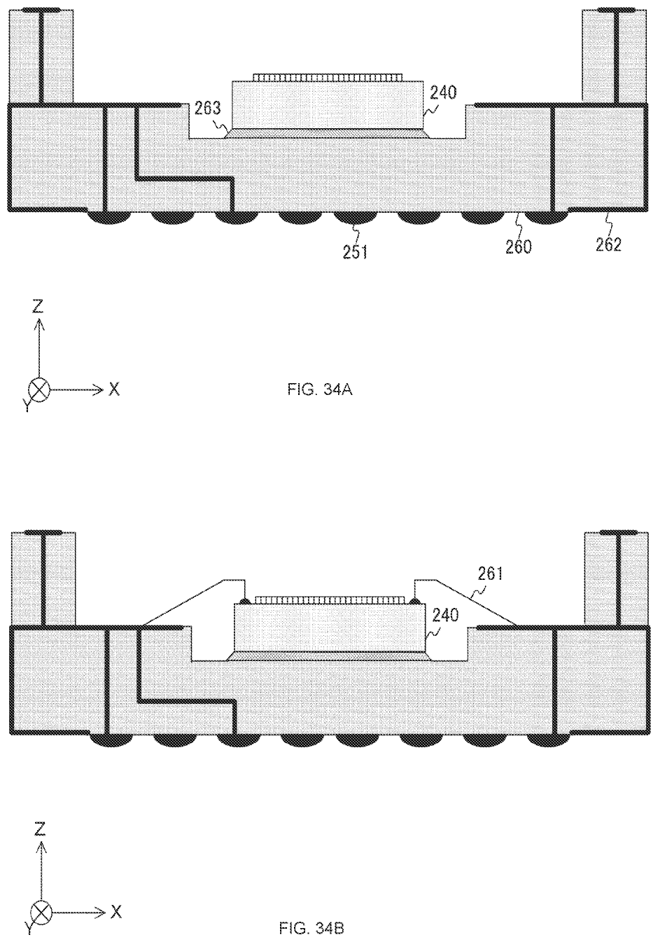

FIG. 34 depicts diagrams illustrating the manufacturing processes of the semiconductor package up to wire bonding according to the fourth embodiment of the present technology. Here, a of FIG. 34 is a diagram illustrating the process of adhering the solid-state image pickup element 240 to the silicon die, and b of FIG. 34 is a diagram illustrating the process of wire bonding.

As exemplified in a of FIG. 34, the manufacturing system adheres the solid-state image pickup element 240 to the silicon die. Then, as exemplified in b of FIG. 34, the manufacturing system connects the solid-state image pickup element 240 to the ceramic substrate 260 with the wires 261.

Then, the manufacturing system seals the recess in the ceramic substrate 260 with the members that have undergone singulation in the process in FIG. 33.

The processes exemplified in FIG. 33 and the processes exemplified in FIG. 34 are executed in parallel. Note that the manufacturing system can also execute those processes sequentially.

In such a way, according to the fourth embodiment of the present technology, the heater 512 heats the transparent member 220 when humidity in the recess exceeds the threshold, so that the transparent member 220 can be prevented from fogging up due to condensation.

### First Modified Example

In the fourth embodiment described above, while the heater 512 heats the transparent member 220 depending on humidity, the optical properties of the transparent member 220, such as incident light intensity or wavelength, are insufficient in some cases. The semiconductor package 200 according to a first modified example of the fourth embodiment is different from that of the fourth embodiment in that a circuit configured to control the optical properties is embedded.

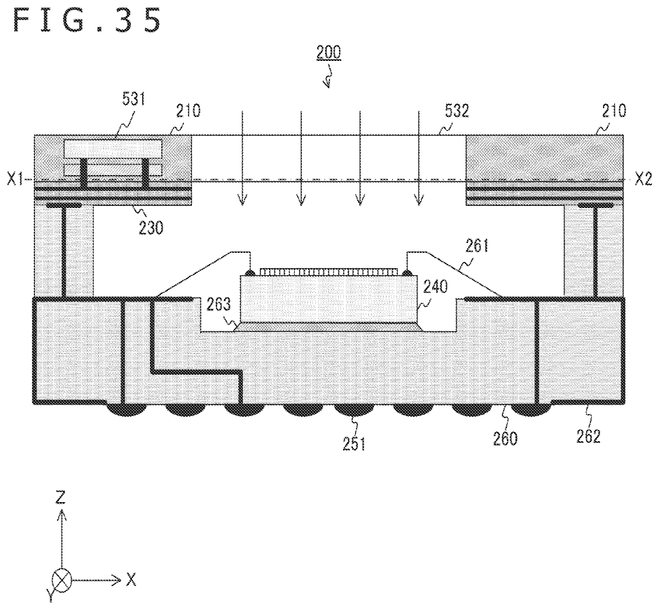

FIG. 35 is a sectional view illustrating a configuration example of the semiconductor package 200 according to the first modified example of the fourth embodiment of the present technology. The semiconductor package 200 according to the first modified example of the fourth embodiment is different from that of the fourth embodiment in that a control circuit 531 is included in place of the humidity sensor 510, and light control glass 532 is included in place of the transparent member 220. Further, the measurement hole 511 is not formed, and the heater 512 is not disposed.

The control circuit 531 controls the optical properties of the light control glass 532. The light control glass 532 changes, under the control of the control circuit 531, its optical properties such as incident light intensity or wavelength.

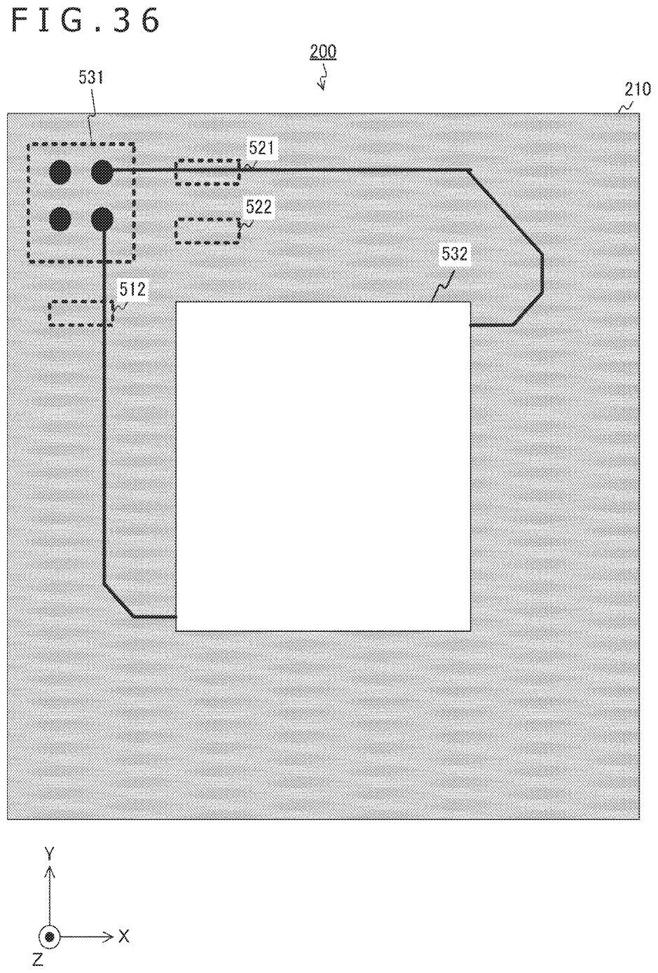

FIG. 36 is an exemplary sectional view of the semiconductor package 200 according to the first modified example of the fourth embodiment of the present technology. FIG. 36 is a sectional view of the semiconductor package 200 taken along the line X1-X2 of FIG. 35. As exemplified in FIG. 36, the control circuit 531 is connected to the light control glass 532 through vias.

Note that, the control circuit 531 is provided in place of the humidity sensor 510 and the heater 512, but the humidity sensor 510 and the heater 512 may not be eliminated, so that all of the humidity sensor 510 and the like and the control circuit 531 can also be disposed. In other words, the first modified example of the fourth embodiment is also applicable to the fourth embodiment.

In such a way, according to the first modified example of the fourth embodiment of the present technology, the control circuit 531 controls the optical properties of the light control glass 532, so that the optical properties can be adjusted to appropriate values.

### Second Modified Example

In the fourth embodiment described above, the heater 512 heats the transparent member 220 depending on humidity, and the wireless transmission of image data is required depending on the use of the semiconductor package 200. The semiconductor package 200 according to a second modified example of the fourth embodiment is different from that of the fourth embodiment in that a wireless circuit is embedded.

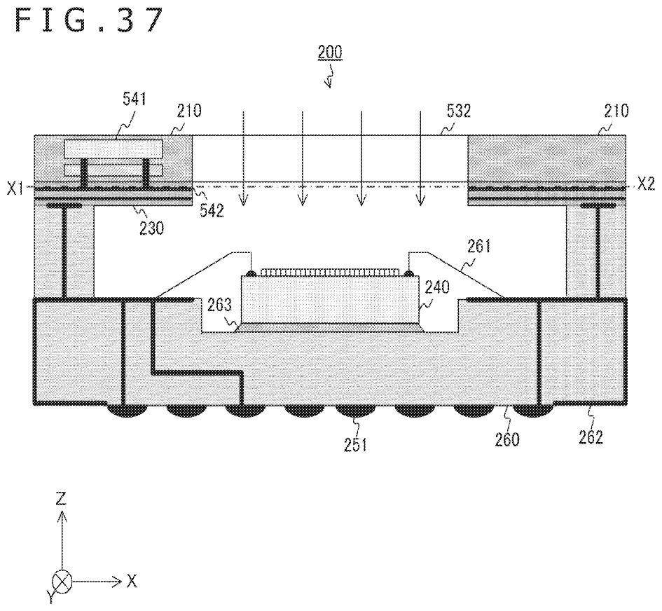

FIG. 37 is a sectional view illustrating a configuration example of the semiconductor package 200 according to the second modified example of the fourth embodiment of the present technology. The semiconductor package 200 according to the second modified example of the fourth embodiment is different that of from the fourth embodiment in that a wireless circuit 541 is included in place of the humidity sensor 510. Further, the measurement hole 511 is not formed, and the heater 512 is not disposed.

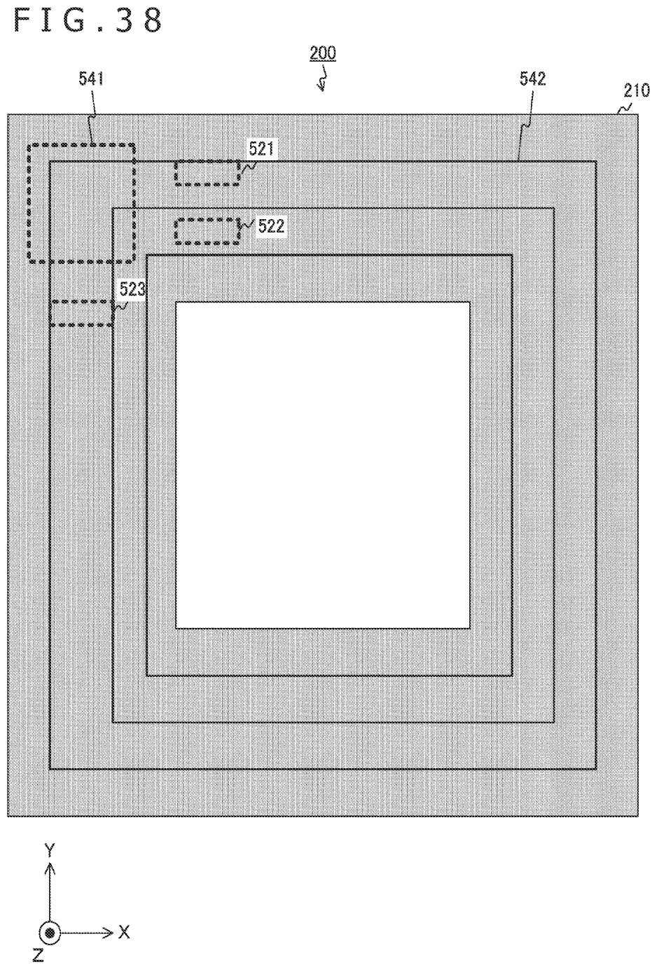

FIG. 38 is an exemplary sectional view of the semiconductor package 200 according to the second modified example of the fourth embodiment of the present technology. FIG. 38 is a sectional view of the semiconductor package 200 taken along the line X1-X2 of FIG. 37. As exemplified in FIG. 38, an antenna 542 is formed in the redistribution layer 230 and connected to the wireless circuit 541.

The wireless circuit 541 performs wireless communication via the antenna 542. For example, the wireless circuit 541 wirelessly transmits image data. Note that, the wireless circuit 541 can also wirelessly receive data from the outside.

Note that, the wireless circuit 541 and the like are provided in place of the humidity sensor 510 and the heater 512, but the humidity sensor 510 and the heater 512 may not be eliminated, so that all of the humidity sensor 510 and the like and the wireless circuit 541 and the like can also be disposed. In other words, the second modified example of the fourth embodiment is also applicable to the fourth embodiment. Further, the first modified example of the fourth embodiment is also applicable to the second modified example of the fourth embodiment

In such a way, according to the second modified example of the fourth embodiment of the present technology, the wireless circuit 541 and the antenna 542 are provided, so that wireless communication can be performed.

### 5. Fifth Embodiment

In the first embodiment described above, the embedded circuits 211 and 212 are embedded around the transparent member 220, but it is difficult to prevent a temperature rise due to heat generated by the operating circuits when the heat release quantity is insufficient. The semiconductor package 200 of a fifth embodiment is different from that of the first embodiment in that a heat release member configured to release heat generated by the embedded circuits 211 and 212 to the outside is further provided.

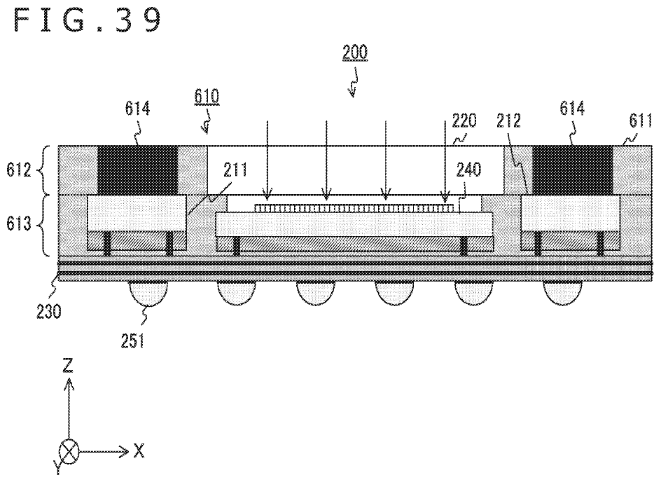

FIG. 39 is a sectional view illustrating a configuration example of the semiconductor package 200 according to the fifth embodiment of the present technology. The semiconductor package 200 of the fifth embodiment includes a composite material 610, the redistribution layer 230, and the external terminals 251.

The composite material 610 is a member obtained by joining the transparent member 220 and an embedding resin 611 together. Further, the solid-state image pickup element 240 is provided under the transparent member 220, and the embedding resin 611 is formed around the transparent member 220 and the solid-state image pickup element 240.

Of the embedding resin 611, in a circuit layer 613 around the solid-state image pickup element 240, the embedded circuits 211 and 212 are embedded. Further, of the embedding resin 611, in a heat release layer 612 around the transparent member 220, a heat release member 614 is embedded.

Further, the redistribution layer 230 is formed under the composite material 610, and the predetermined number of external terminals 251 are mounted under the redistribution layer 230.

The heat release member 614 releases heat generated by the embedded circuits 211 and 212. The heat release member 614 is formed in the embedding resin 611 to extend from the embedded circuits 211 and 212 to the upper surface of the semiconductor package 200. As the heat release member 614, metal with good thermal conductivity such as copper is used.

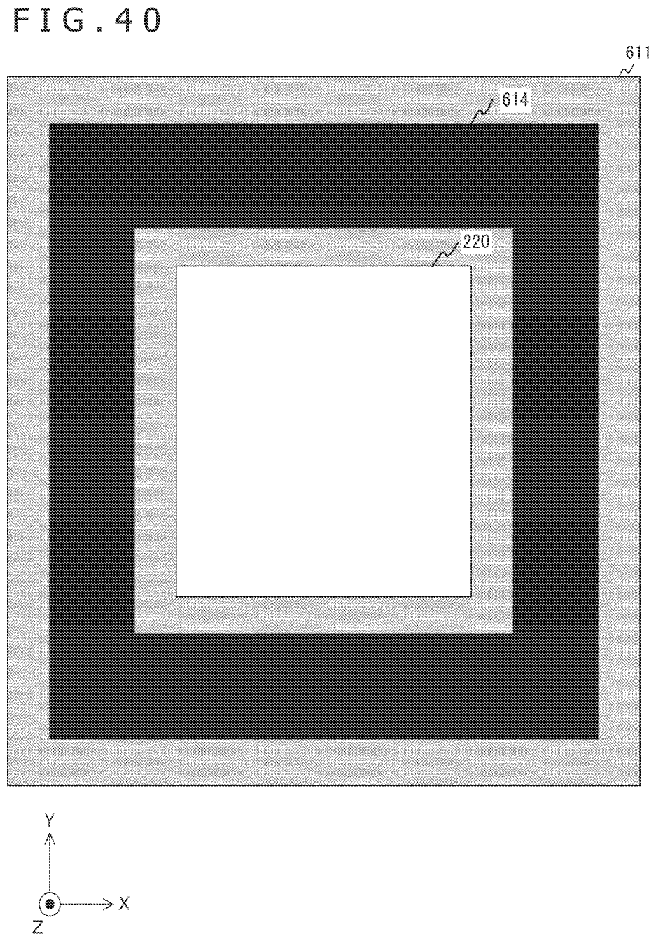

FIG. 40 is an exemplary top view of the semiconductor package 200 according to the fifth embodiment of the present technology. As exemplified in FIG. 40, in the embedding resin 210, the rectangular heat release member 614 is formed around the transparent member 220. With heat being released by the heat release member 614, a temperature rise that may be caused by the operating embedded circuits 211 and 212 can be prevented.

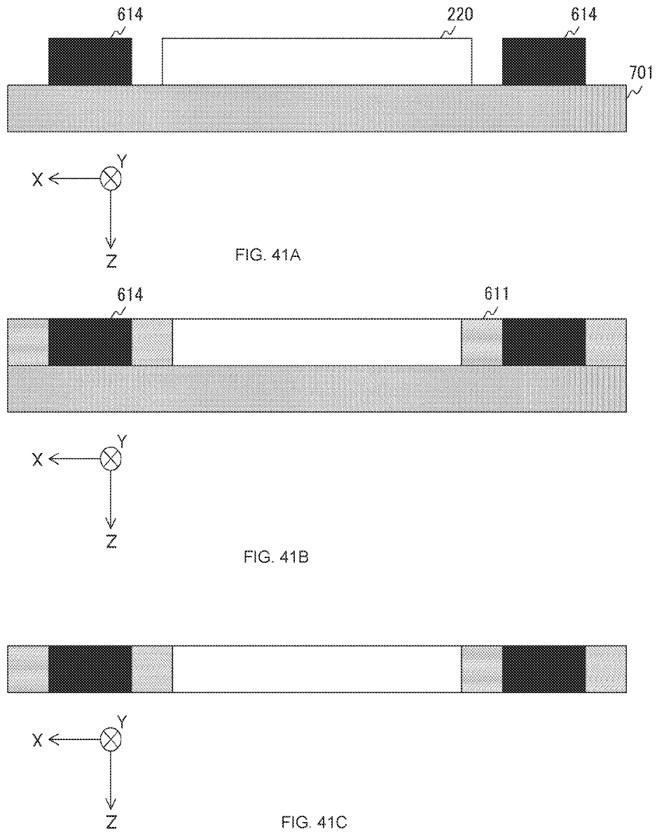

FIG. 41 depicts diagrams illustrating the manufacturing processes of the semiconductor package up to the peeling off of the support substrate 701 according to the fifth embodiment of the present technology. Here, a of FIG. 41 is a diagram illustrating the process of placing the transparent member 220 and the heat release member 614 on the support substrate 701, b of FIG. 41 is a diagram illustrating the process of forming the embedding resin 611, and c of FIG. 41 is a diagram illustrating the process of peeling off the support substrate 701.

As exemplified in a of FIG. 41, the manufacturing system places the transparent member 220 on the support substrate 701, and places the heat release member 614 around the transparent member 220. Then, as exemplified in b of FIG. 41, the manufacturing system forms the embedding resin 210 around the transparent member 220 to embed the heat release member 614. Subsequently, the manufacturing system peels off the support substrate 701 as exemplified in c of FIG. 41.

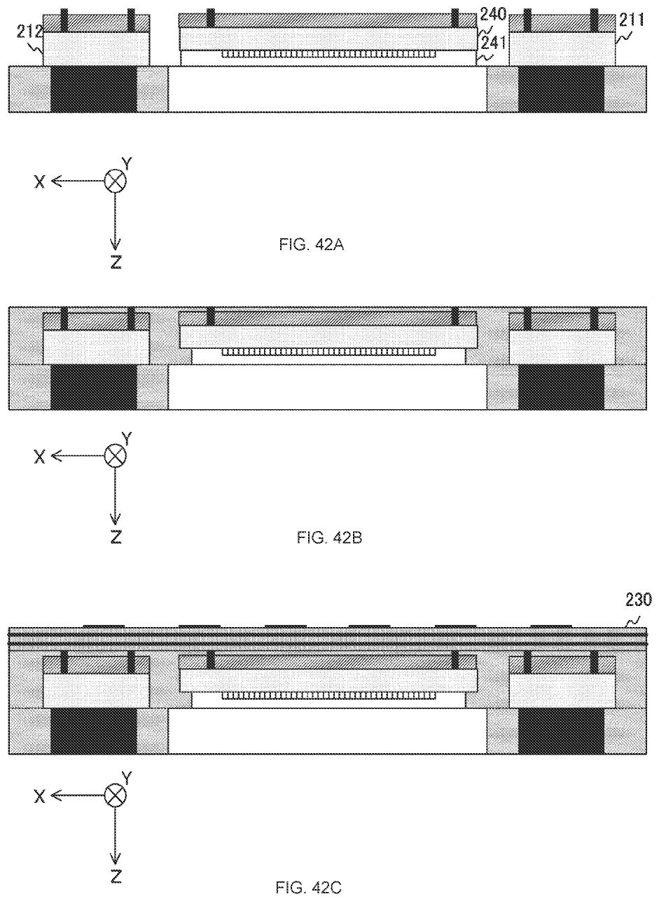

FIG. 42 depicts diagrams illustrating the manufacturing processes of the semiconductor package 200 up to the formation of the redistribution layer 230 according to the fifth embodiment of the present technology. Here, a of FIG. 42 is a diagram illustrating the process of adhering the embedded circuits 211 and 212 and the solid-state image pickup element 240 to the composite material, b of FIG. 42 is a diagram illustrating the process of forming the embedding resin 611, and c of FIG. 42 is a diagram illustrating the process of forming the redistribution layer 230.

As exemplified in a of FIG. 42, the manufacturing system adheres the embedded circuits 211 and 212 and the solid-state image pickup element 240 to the composite material with the respective terminal-side surfaces facing downward. The filter surface of the solid-state image pickup element 240 is covered with a cover 241. The heat release member 614 and the embedded circuits 211 and 212 are desirably adhered to each other with a material with good thermal conductivity.

Then, as exemplified in b of FIG. 42, the manufacturing system forms the embedding resin 611 around the solid-state image pickup element 240 to embed the embedded circuits 211 and 212. Subsequently, as exemplified in c of FIG. 42, the manufacturing system forms the redistribution layer 230 and exposes the terminals by grinding.

Then, the manufacturing system places the external terminals 251 to manufacture the semiconductor package 200 having the structure exemplified in FIG. 39.

Note that, the manufacturing system peels off the support substrate 701 and then adheres the solid-state image pickup element 240 and the like to the composite material, but the present invention is not limited to this manufacturing method. In a case where warpage is a problem in terms of process, the solid-state image pickup element 240 and the like can also be adhered to the composite material while the support substrate 701 remains.

In such a way, according to the fifth embodiment of the present technology, the heat release member 614 configured to release heat generated by the embedded circuits 211 and 212 is embedded, so that a temperature rise that may be caused by the operating embedded circuits 211 and 212 can be prevented.

### First Modified Example

In the fifth embodiment described above, the transparent member 220 is placed on the support substrate 701, and the heat release member 614 is placed around the transparent member 220. This manufacturing method, however, has a difficulty in reducing manufacturing lead time and cost of the semiconductor package 200. A manufacturing method according to a first modified example of the fifth embodiment is different from that of the fifth embodiment in that the process of placing the transparent member 220 and the heat release member 614 is simplified.

FIG. 43 is a diagram illustrating the manufacturing process of the transparent member 220 and the heat release member 614 according to the first modified example of the fifth embodiment of the present technology. As exemplified in FIG. 43, the manufacturing system prepares a circular glass-mounted wafer 705. The glass-mounted wafer 705 is divided into a plurality of chip areas. In the area indicated by the dotted line of FIG. 43, the area surrounded by the solid line around the rectangle corresponds to the chip area. On each chip area, the transparent member 220 and the heat release member 614 formed around the transparent member 220 are provided.

The manufacturing system singulates the glass-mounted wafer 705 along the dicing lines. With this, the transparent member 220 and the heat release member 614 are provided on each chip. The processes after dicing are similar to those of the fifth embodiment.

In such a way, according to the first modified example of the fifth embodiment of the present technology, the glass-mounted wafer 705 is singulated to provide the transparent member 220 and the heat release member 614 on each chip, so that the manufacturing process can be simplified.

### Second Modified Example

In the fifth embodiment described above, the image plane-side surface of the solid-state image pickup element 240 is adhered to the composite material 610, and the solid-state image pickup element 240 and the transparent member 220 are desirably spaced apart from each other. The semiconductor package 200 according to a second modified example of the fifth embodiment is different from that of the fifth embodiment in that a resin dam is provided, so that the solid-state image pickup element 240 and the transparent member 220 are spaced apart from each other.

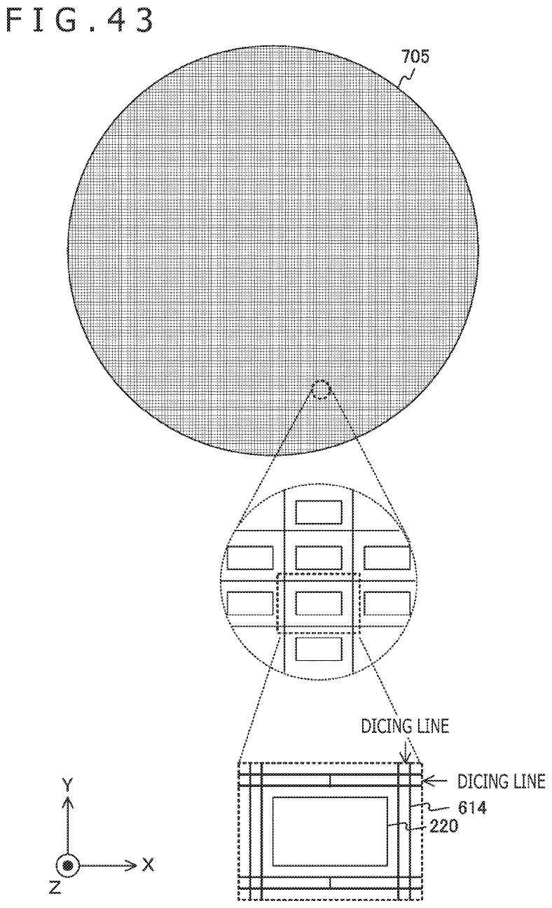

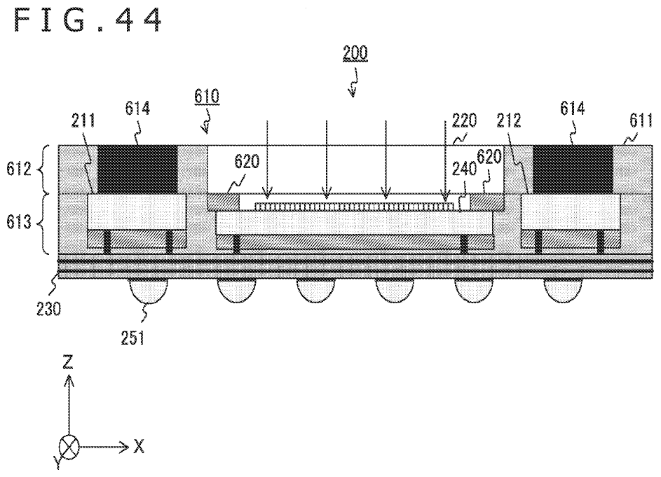

FIG. 44 is a sectional view illustrating a configuration example of the semiconductor package 200 according to the second modified example of the fifth embodiment of the present technology. The semiconductor package 200 according to the second modified example of the fifth embodiment is different from that of the fifth embodiment in that a resin dam 620 is further included.

The resin dam 620 is a resin formed between the periphery of the pixel array portion of the solid-state image pickup element and the transparent member 220.

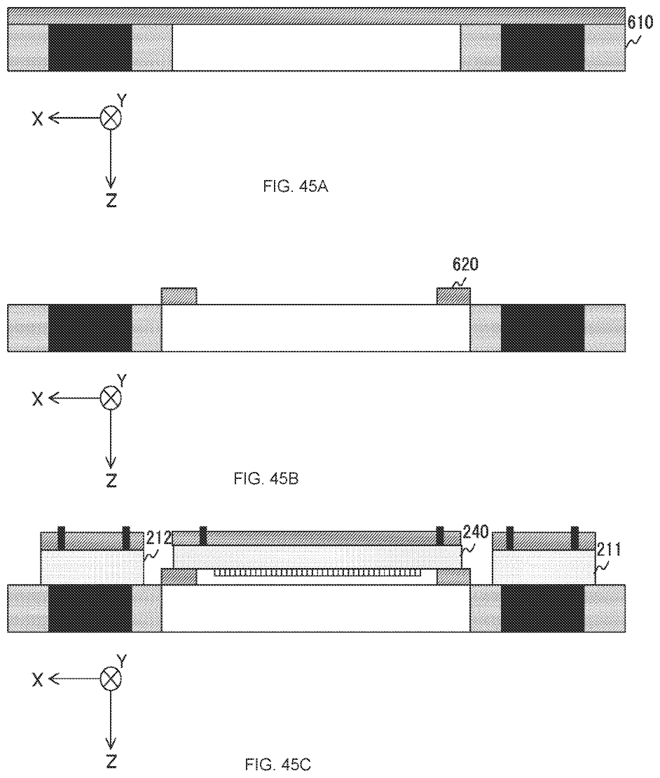

FIG. 45 depicts diagrams illustrating the manufacturing processes of the semiconductor package 200 up to the mounting of the solid-state image pickup element 240 and the embedded circuits 211 and 212 according to the second modified example of the fifth embodiment of the present technology. Here, a of FIG. 45 is a diagram illustrating the process of applying a UV curable resin, b of FIG. 45 is a diagram illustrating the process of forming the resin dam 620, and c of FIG. 45 is a diagram illustrating the process of mounting the solid-state image pickup element 240 and the embedded circuits 211 and 212.

As exemplified in a of FIG. 45, the manufacturing system applies a UV curable resin or the like to the surface of the composite material 610 having embedded therein the heat release member 614. Then, the manufacturing system cures only the portion of the UV curable resin that is to be left as the resin dam 620, by ultraviolet irradiation, with use of a mask, and removes the remaining with a developing solution, to thereby form the resin dam 620. Subsequently, the manufacturing system mounts the solid-state image pickup element 240 and the embedded circuits 211 and 212 as exemplified in c of FIG. 45.

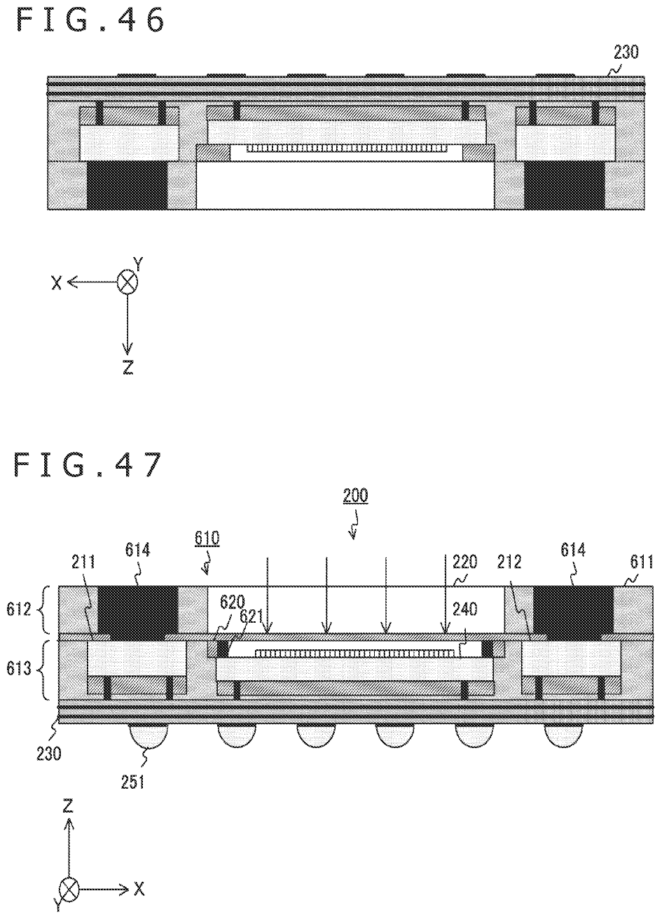

FIG. 46 is a diagram illustrating the process of forming the redistribution layer 230 according to the second modified example of the fifth embodiment of the present technology. As exemplified in FIG. 46, the manufacturing system forms the redistribution layer 230 and exposes the terminals by grinding. Then, the manufacturing system places the external terminals 251 to manufacture the semiconductor package 200 having the structure exemplified in FIG. 39.

In such a way, according to the second modified example of the fifth embodiment of the present technology, the resin dam 620 is disposed between the solid-state image pickup element 240 and the transparent member 220, so that the solid-state image pickup element 240 and the transparent member 220 can be spaced apart from each other.

### Third Modified Example

In the second modified example of the fifth embodiment described above, the resin dam 620 is disposed between the solid-state image pickup element 240 and the transparent member 220. However, in this configuration, since the resin dam 620 is liquid before being cured, there is a risk that the solid-state image pickup element 240 is shifted from a given position. This phenomenon is also called a chip shift. The semiconductor package 200 according to a third modified example of the fifth embodiment is different from that of the second modified example of the fifth embodiment in that a chip shift is prevented by bump connection.

FIG. 47 is a sectional view illustrating a configuration example of the semiconductor package 200 according to the third modified example of the fifth embodiment of the present technology. The semiconductor package 200 according to the third modified example of the fifth embodiment is different from that of the second modified example of the fifth embodiment in that bumps 621 are further provided.

The bumps 621 are disposed around the pixel array portion of the solid-state image pickup element 240. The solid-state image pickup element 240 and the transparent member 220 are connected to each other via the bumps 621. With this, the position of the solid-state image pickup element 240 is fixed, so that a chip shift can be prevented.

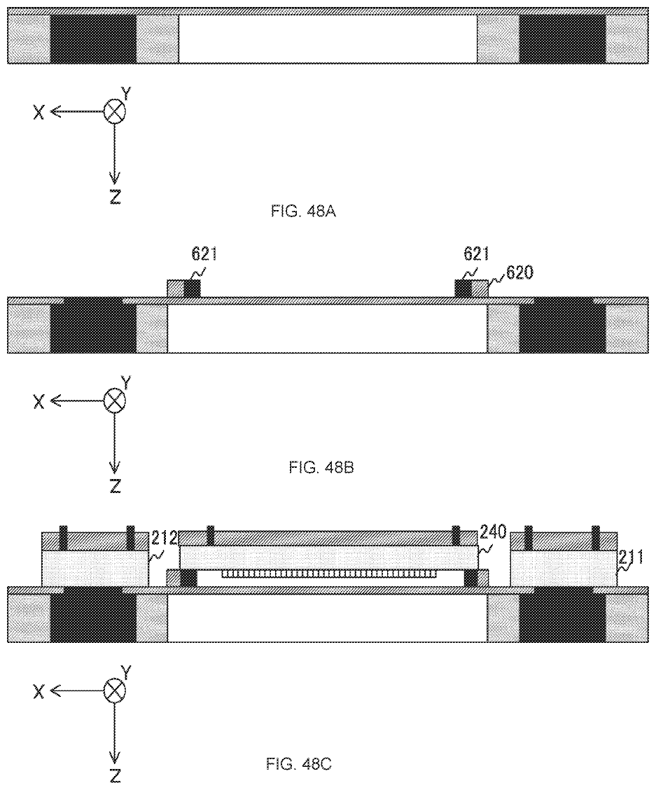

FIG. 48 depicts diagrams illustrating the manufacturing processes of the semiconductor package 200 up to the mounting of the solid-state image pickup element 240 and the embedded circuits 211 and 212 according to the third modified example of the fifth embodiment of the present technology. Here, a of FIG. 48 is a diagram illustrating the process of applying a UV curable resin, b of FIG. 48 is a diagram illustrating the process of forming the bumps 621 and the resin dam 620, and c of FIG. 48 is a diagram illustrating the process of mounting the solid-state image pickup element 240 and the embedded circuits 211 and 212.

As exemplified in a of FIG. 48, the manufacturing system applies a UV curable resin or the like to the surface of the composite material 610 having embedded therein the heat release member 614. Then, the manufacturing system cures only the portion of the UV curable resin that is to be left as the resin dam 620, by ultraviolet irradiation, with use of a mask, and removes the remaining with a developing solution, to thereby form the resin dam 620. Further, the manufacturing system provides the predetermined number of bumps 621 on the inner side of the resin dam 620. Subsequently, the manufacturing system mounts the solid-state image pickup element 240 and the embedded circuits 211 and 212 as exemplified in c of FIG. 48. The solid-state image pickup element 240 is connected to the transparent member 220 via the bumps 621.

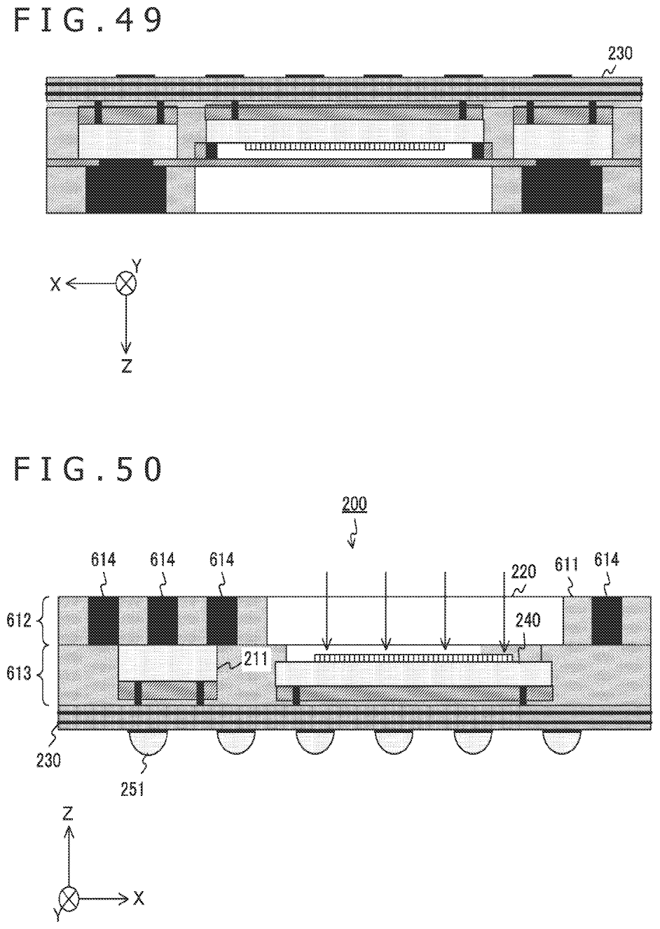

FIG. 49 is a diagram illustrating the process of forming the redistribution layer 230 according to the third modified example of the fifth embodiment of the present technology. As exemplified in FIG. 49, the manufacturing system forms the redistribution layer 230 and exposes the terminals by grinding. Then, the manufacturing system places the external terminals 251 to manufacture the semiconductor package 200 having the structure exemplified in FIG. 39.

Note that, the solid-state image pickup element 240 is disposed at the center of the semiconductor package 200 in the fifth embodiment and the first to third modified examples thereof, but the present invention is not limited to this configuration. As described later, the solid-state image pickup element 240 can also be disposed at a position shifted from the center of the semiconductor package 200. Further, the composite material 610 may have a heat path utilizing the redistribution layer 230 to allow heat generated by the solid-state image pickup element 240 itself to move to the upper surface through the heat release path. To realize this structure, for example, it is only necessary to further dispose a heat release member such as metal that extends from the redistribution layer 230 to the upper surface of the semiconductor package 200 through the embedding resin 611.

In such a way, according to the third modified example of the fifth embodiment of the present technology, the solid-state image pickup element 240 and the transparent member 220 are connected to each other via the bumps 621, so that a position shift of the solid-state image pickup element 240 (in other words, a chip shift) can be prevented.

### Fourth Modified Example

In the fifth embodiment described above, the heat release member 614 having the rectangular periphery is formed around the transparent member 220 when seen from the Z direction, and the heat release member 614 may have a columnar shape. A fourth modified example of the fifth embodiment is different from the fifth embodiment in that a columnar heat release member 614 is disposed.

FIG. 50 is a sectional view illustrating a configuration example of the semiconductor package 200 according to the fourth modified example of the fifth embodiment of the present technology. The semiconductor package 200 according to the fourth modified example of the fifth embodiment is different from that of the fifth embodiment in that the heat release member 614 has a columnar shape (for example, a cylindrical shape) extending along the Z direction. Further, the solid-state image pickup element 240 is disposed at a position shifted from the center of the semiconductor package 200.

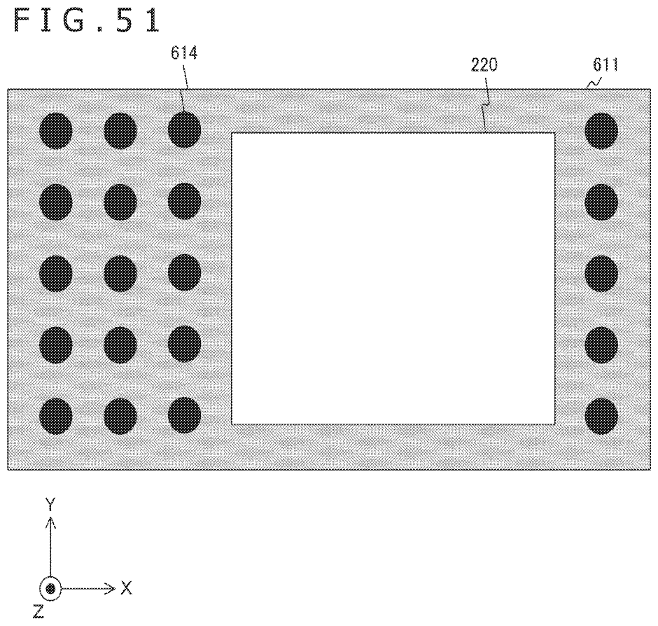

FIG. 51 is a sectional view illustrating a configuration example of the semiconductor package 200 according to a fifth modified example of the fifth embodiment of the present technology. As exemplified in FIG. 51, in the case where the heat release member 614 has the cylindrical shape, the heat release member 614 has the circular shape when seen from the Z direction.

In such a way, according to the fourth modified example of the fifth embodiment of the present technology, the columnar heat release member 614 is embedded, so that a temperature rise that may be caused by the operating embedded circuits 211 and 212 can be prevented.

### 6. Application Example to Moving Body

The technology according to the present disclosure (present technology) is applicable to various products. For example, the technology according to the present disclosure may be realized as a device that is mounted on any kind of moving bodies, for example, vehicles, electric vehicles, hybrid electric vehicles, motorcycles, bicycles, personal mobilities, airplanes, drones, ships, and robots.

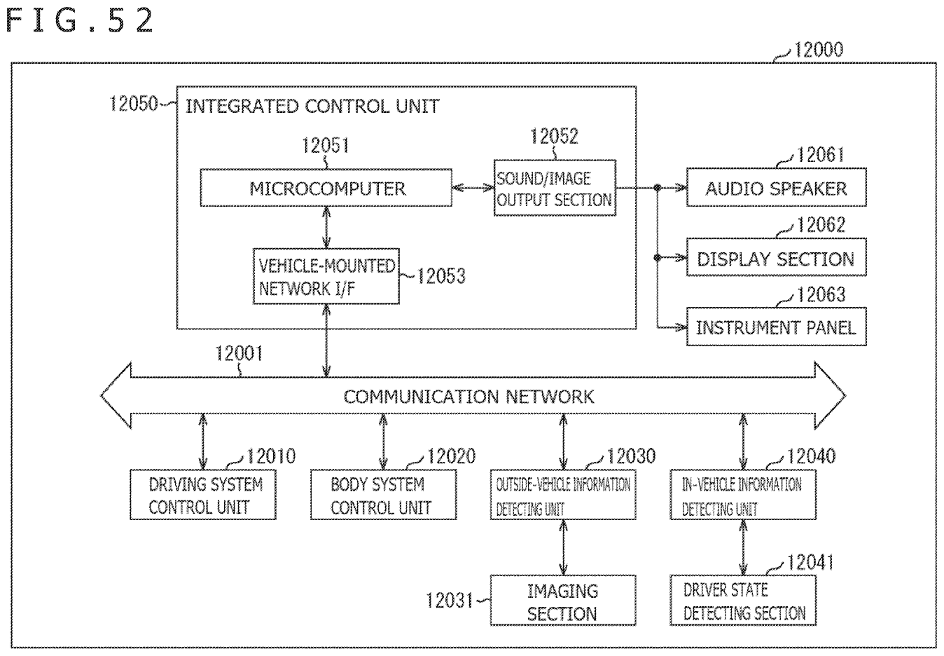

FIG. 52 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 52, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 52, an audio speaker 12061, a display section 12062, and an instrument panel 12063 are illustrated as the output device. The display section 12062 may, for example, include at least one of an on-board display and a head-up display.

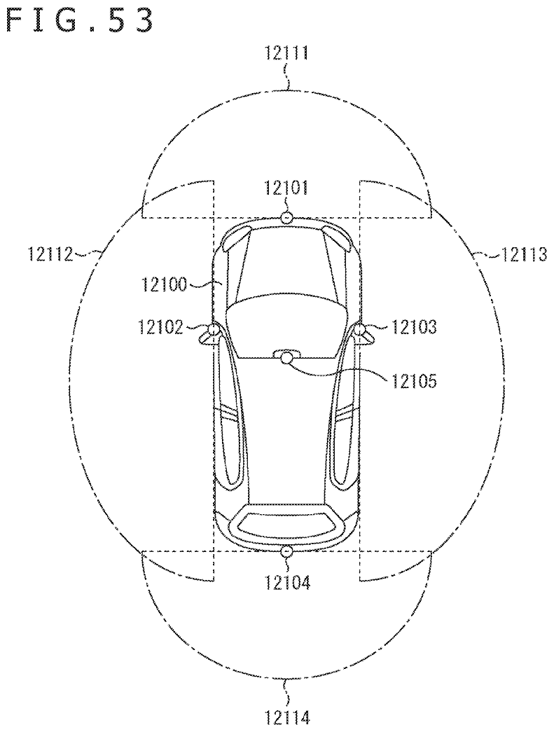

FIG. 53 is a diagram depicting an example of the installation position of the imaging section 12031.

In FIG. 53, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 53 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The exemplary vehicle control system to which the technology according to the present disclosure may be applied has been described above. The technology according to the present disclosure may be applied to the imaging section 12031 among the above-mentioned configurations, for example. Specifically, the electronic device 100 of FIG. 1 is applicable to the imaging section 12031. By applying the technology according to the present disclosure to the imaging section 12031, advanced functions can be achieved with the added circuits while an increase in size of the imaging section 12031 is prevented.

Note that, the above-mentioned embodiments are examples for implementing the present technology, and the matters in the embodiments have correspondence relations with matters to define the invention in the claims. In a similar manner, the matters to define the invention in the claims have correspondence relations with the matters in the embodiments of the present technology denoted by the same names. However, the present technology is not limited to the embodiments, and various modifications of the embodiments can be implemented without departing from the gist of the present technology.

Note that, the effects described herein are only exemplary and not limitative, and other effects may be provided.

Note that, the present technology can also take the following configurations.

(1) A semiconductor package including:

a transparent member;

an embedding resin formed around the transparent member;

an embedded circuit embedded in the embedding resin; and

a solid-state image pickup element configured to perform photoelectric conversion on light that has passed through the transparent member and thereby generate image data.

(2) The semiconductor package according to Item (1), further including:

a redistribution layer having wired therein a signal line for connecting the embedded circuit and the solid-state image pickup element to each other.

(3) The semiconductor package according to Item (2), further including:

an external terminal disposed in a fan-out area.

(4) The semiconductor package according to Item (2), further including:

an external terminal disposed in each of a fan-out area and a fan-in area.

(5) The semiconductor package according to any one of Items (2) to (4), further including:

a frame that has an opening portion formed in an area corresponding to the transparent member and is laminated on the embedding resin.

(6) The semiconductor package according to Item (2), further including:

a ceramic substrate having formed therein a recess; and

an external terminal formed on the ceramic substrate,

in which the solid-state image pickup element is provided in the recess and connected to the ceramic substrate with a wire.

(7) The semiconductor package according to Item (6), further including:

a heater configured to heat the transparent member in a case where humidity in the recess exceeds a predetermined threshold,

in which the embedded circuit includes a humidity sensor configured to measure the humidity and detect whether the humidity exceeds the threshold or not.

(8) The semiconductor package according to Item (6) or (7), in which the embedded circuit includes a control circuit configured to control an optical property of the transparent member.

(9) The semiconductor package according to any one of Items (6) to (8), further including:

an antenna,

in which the embedded circuit includes a wireless circuit configured to perform wireless communication via the antenna.

(10) The semiconductor package according to Item (1), further including:

a heat release member embedded in the embedding resin,

in which the heat release member releases heat generated by the embedded circuit.

(11) The semiconductor package according to Item (10), in which the heat release member has a columnar shape.

(12) The semiconductor package according to Item (10) or (11), further including:

a resin dam formed between a periphery of a pixel array portion of the solid-state image pickup element and the transparent member.

(13) The semiconductor package according to Item (12), in which the solid-state image pickup element is connected to the transparent member via a bump.

(14) An electronic device including:

a transparent member;

an embedding resin formed around the transparent member;

an embedded circuit embedded in the embedding resin;

a solid-state image pickup element configured to perform photoelectric conversion on light that has passed through the transparent member and thereby generate image data; and

an optical section configured to collect incident light and guide the incident light to the transparent member.

(15) A method of manufacturing a semiconductor package, including:

an embedding resin forming procedure of forming an embedding resin around a transparent member on a support substrate that has placed thereon the transparent member and an embedded circuit and embedding the embedded circuit in the embedding resin; and

an implementing procedure of implementing a solid-state image pickup element configured to generate image data.

(16) The method of manufacturing a semiconductor package according to Item (15), further including:

a redistribution layer forming procedure of forming a redistribution layer having wired therein a signal line for connecting the embedded circuit and the solid-state image pickup element to each other; and

a peeling off procedure of peeling off the support substrate after the solid-state image pickup element has been implemented.

(17) The method of manufacturing a semiconductor package according to Item (15), further including:

a redistribution layer forming procedure of forming a redistribution layer having wired therein a signal line for connecting the embedded circuit and the solid-state image pickup element to each other; and

a peeling off procedure of peeling off the support substrate after the redistribution layer has been formed, in which, in the disposing procedure, the solid-state image pickup element is implemented after the support substrate has been peeled off.

(18) The method of manufacturing a semiconductor package according to Item (15), further including:

a dicing procedure of performing singulation of a plurality of chip areas on a wafer, the plurality of chip areas each including a transparent member and a heat release member formed around the transparent member.

(19) A method of manufacturing a semiconductor package, including:

an embedding resin forming procedure of forming an embedding resin around a transparent member to embed an embedded circuit in the embedding resin; and

a laminating procedure of performing lamination and thermocompression bonding of a composite material including the transparent member and the embedding resin, a plurality of base materials each having formed therein a signal line, a redistribution layer, and a solid-state image pickup element configured to perform photoelectric conversion on light that has passed through the transparent member and thereby generate image data.

### REFERENCE SIGNS LIST

100: Electronic device
110: Optical section
120: DSP circuit
130: Display section
140: Operation section
150: Bus
160: Frame memory
170: Storage section
180: Power supply section
200: Semiconductor package
210, 611: Embedding resin
211 to 213: Embedded circuit
220: Transparent member
230: Redistribution layer
231: TMV
240: Solid-state image pickup element
251: External terminal
252, 621: Bump
253: Underfill material
260: Ceramic substrate
261: Wire
262, 413: Signal line
263: Adhesive
270: Frame
310 to 318, 521 to 523: Passive component
410: Laminate substrate
411, 412: Incorporated component
421, 422: Implemented component
450, 460: Base material
510: Temperature sensor
511: Measurement hole
512: Heater
531: Control circuit
532: Light control glass
541: Wireless circuit
542: Antenna
610: Composite material
612: Heat release layer
613: Circuit layer
614: Heat release member
620: Resin dam
701: Support substrate
702: Image sensor wafer
705: Glass-mounted wafer
12031: Imaging section

1. A semiconductor package comprising:
a transparent member;
an embedding resin formed around the transparent member;
an embedded circuit embedded in the embedding resin; and
a solid-state image pickup element configured to perform photoelectric conversion on light that has passed through the transparent member and thereby generate image data.

2. The semiconductor package according to claim 1, further comprising:
a redistribution layer having wired therein a signal line for connecting the embedded circuit and the solid-state image pickup element to each other.

3. The semiconductor package according to claim 2, further comprising:
an external terminal disposed in a fan-out area.

4. The semiconductor package according to claim 2, further comprising:
an external terminal disposed in each of a fan-out area and a fan-in area.

5. The semiconductor package according to claim 2, further comprising:
a frame that has an opening portion formed in an area corresponding to the transparent member and is laminated on the embedding resin.

6. The semiconductor package according to claim 2, further comprising:
a ceramic substrate having formed therein a recess; and
an external terminal formed on the ceramic substrate,
wherein the solid-state image pickup element is provided in the recess and connected to the ceramic substrate with a wire.

7. The semiconductor package according to claim 6, further comprising:
a heater configured to heat the transparent member in a case where humidity in the recess exceeds a predetermined threshold,
wherein the embedded circuit includes a humidity sensor configured to measure the humidity and detect whether the humidity exceeds the threshold or not.

8. The semiconductor package according to claim 6, wherein the embedded circuit includes a control circuit configured to control an optical property of the transparent member.

9. The semiconductor package according to claim 6, further comprising:
an antenna,
wherein the embedded circuit includes a wireless circuit configured to perform wireless communication via the antenna.

10. The semiconductor package according to claim 1, further comprising:
a heat release member embedded in the embedding resin,
wherein the heat release member releases heat generated by the embedded circuit.

11. The semiconductor package according to claim 10, wherein the heat release member has a columnar shape.

12. The semiconductor package according to claim 10, further comprising:
a resin dam formed between a periphery of a pixel array portion of the solid-state image pickup element and the transparent member.

13. The semiconductor package according to claim 12, wherein the solid-state image pickup element is connected to the transparent member via a bump.

14. An electronic device comprising:
a transparent member;
an embedding resin formed around the transparent member;
an embedded circuit embedded in the embedding resin;
a solid-state image pickup element configured to perform photoelectric conversion on light that has passed through the transparent member and thereby generate image data; and
an optical section configured to collect incident light and guide the incident light to the transparent member.

15. A method of manufacturing a semiconductor package, comprising:
an embedding resin forming procedure of forming an embedding resin around a transparent member on a support substrate that has placed thereon the transparent member and an embedded circuit and thereby embedding the embedded circuit in the embedding resin; and
an implementing procedure of implementing a solid-state image pickup element configured to generate image data.

16. The method of manufacturing a semiconductor package according to claim 15, further comprising:
a redistribution layer forming procedure of forming a redistribution layer having wired therein a signal line for connecting the embedded circuit and the solid-state image pickup element to each other; and
a peeling off procedure of peeling off the support substrate after the solid-state image pickup element has been implemented.

17. The method of manufacturing a semiconductor package according to claim 15, further comprising:
a redistribution layer forming procedure of forming a redistribution layer having wired therein a signal line for connecting the embedded circuit and the solid-state image pickup element to each other; and
a peeling off procedure of peeling off the support substrate after the redistribution layer has been formed,
wherein, in the disposing procedure, the solid-state image pickup element is implemented after the support substrate has been peeled off.

18. The method of manufacturing a semiconductor package according to claim 15, further comprising:
a dicing procedure of performing singulation of a plurality of chip areas on a wafer, the plurality of chip areas each including a transparent member and a heat release member formed around the transparent member.

19. A method of manufacturing a semiconductor package, comprising:
an embedding resin forming procedure of forming an embedding resin around a transparent member to embed an embedded circuit in the embedding resin; and
a laminating procedure of performing lamination and thermocompression bonding of a composite material including the transparent member and the embedding resin, a plurality of base materials each having formed therein a signal line, a redistribution layer, and a solid-state image pickup element configured to perform photoelectric conversion on light that has passed through the transparent member and thereby generate image data.
